(19) United States
(12) Patent Application Publication
(10) Pub. No.: US 2026/0231597 A1
(43) Pub. Date: Aug. 6, 2026

(54) DISPLAY PANEL AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Yichi ZHANG, Beijing (CN); Dong LI, Beijing (CN); Jian XU, Beijing (CN)

(21) Appl. No.: 19/152,187

(22) PCT Filed: Feb. 24, 2023
(86) PCT No.: PCT/CN2023/078220

§ 371 Date: Jul. 30, 2025

(51) Int. Cl. H10K 50/115; H10K 50/165; H10K 50/19; H10K 59/122; H10K 59/131; H10K 59/80; H10K 102/00

(52) U.S. Cl. CPC H10K 50/115; H10K 50/165; H10K 50/19; H10K 59/122; H10K 59/131; H10K 59/873; H10K 2102/351

(57) ABSTRACT

The present disclosure relates to a display panel and a display device. The display panel includes a base substrate and a pixel layer stacked at a side of the base substrate. The pixel layer includes at least two regions, each of the at least two regions is provided with at least one quantum dot material layer, and the number of the at least one quantum dot material layer provided in one region is greater than the number of the at least one quantum dot material layer provided in the other region.

### CROSS-REFERENCE TO RELATED APPLICATION(S)

This application is the 371 application of PCT Application No. PCT/CN2023/078220, filed on Feb. 24, 2023, the entire contents of which are incorporated herein by reference in its entirety.

### TECHNICAL FIELD

The present disclosure relates to the display technical field, and in particular, to a display panel and a display device.

### BACKGROUND

Quantum Dot Light Emitting Diodes (QLEDs) have the advantages of high color gamut, self-luminescence, low starting voltage, and fast response speed, etc., and thus they have received widespread attention in the display field. The working principle of a quantum dot light emitting diode is as follows: electrons and holes are injected into a quantum dot light-emitting layer from both sides, and these electrons and holes are recombined in the quantum dot light-emitting layer to release photons.

It should be noted that the information disclosed in the above background section is only used to enhance the understanding of the background of the present disclosure, and therefore may include information that does not constitute prior art known to those of ordinary skill in this art.

### SUMMARY

The purpose of the present disclosure is to overcome the above-mentioned deficiency in related art and provide a display panel and a display device to improve the balance of lifespans among sub-pixels on a display panel.

According to a first aspect of the present disclosure, there is provided a display panel, including a base substrate and a pixel layer stacked at a side of the base substrate. The pixel layer includes at least two regions, each of the two regions is provided with a quantum dot material layer, and the number of the quantum dot material layer provided in one region is greater than the number of the quantum dot material layer provided in the other region.

In an implementation of the present disclosure, the pixel layer includes a first quantum dot light-emitting unit and a second quantum dot light-emitting unit arranged side by side;
wherein the first quantum dot light-emitting unit includes a first pixel electrode, n first quantum dot tandem layers and a first common electrode which are stacked in sequence at the side of the base substrate, wherein the second quantum dot light-emitting unit includes a second pixel electrode, m second quantum dot tandem layers and a second common electrode which are stacked in sequence at the side of the base substrate; wherein one quantum dot material layer is respectively provided in the first quantum dot tandem layers and the second quantum dot tandem layers;
wherein a light-emitting wavelength of the first quantum dot light-emitting unit is shorter than a light-emitting wavelength of the second quantum dot light-emitting unit;
wherein n and m are both positive integers greater than or equal to 1, and n>m.

According to an implementation of the present disclosure, n is greater than m by 1 or 2.

According to an implementation of the present disclosure, a step difference between a surface of the first quantum dot light-emitting unit away from the base substrate and a surface of the second quantum dot light-emitting unit away from the base substrate does not exceed 400 nm.

According to an implementation of the present disclosure, the display panel further includes a thin film encapsulation layer at a side of the pixel layer away from the base substrate, and a thickness of a part of the thin film encapsulation layer that overlaps with the first quantum dot light-emitting unit is smaller than a thickness of a part of the thin film encapsulation layer that overlaps with the second quantum dot light-emitting unit.

According to an implementation of the present disclosure, the second quantum dot light-emitting unit includes a quantum dot light-emitting unit of a color, or includes quantum dot light-emitting units of a plurality of different colors;
wherein an area ratio of the first quantum dot light-emitting unit is greater than an area ratio of a quantum dot light-emitting unit of any one of the colors in the second quantum dot light-emitting unit.

According to an implementation of the present disclosure, the display panel further includes a driving layer between the base substrate and the pixel layer, the driving layer has a first pixel driving circuit configured to drive the first quantum dot light-emitting unit and a second pixel driving circuit configured to drive the second quantum dot light-emitting unit, and the driving layer includes a first power supply voltage line connected to the first pixel driving circuit and a second power supply voltage line connected to the second pixel driving circuit;
wherein the first pixel electrode is electrically connected to the first power supply voltage line through the first pixel driving circuit, and the first quantum dot light-emitting unit is configured to emit light under driving of a driving current between the first power supply voltage line and the first common electrode;
wherein the second pixel electrode is electrically connected to the second power supply voltage line through the second pixel driving circuit, and the second quantum dot light-emitting unit is configured to emit light under driving of a driving current between the second power supply voltage line and the second common electrode;
wherein the first power supply voltage line and the second power supply voltage line are capable of being applied with different power supply voltages respectively.

According to an implementation of the present disclosure, a width of the first power supply voltage line is greater than a width of the second power supply voltage line.

According to an implementation of the present disclosure, the second quantum dot light-emitting unit includes a quantum dot light-emitting unit of a color, or includes quantum dot light-emitting units of a plurality of different colors;
wherein in the pixel layer, quantum dot light-emitting units are arranged in an array, wherein quantum dot light-emitting units arranged in a same column are quantum dot light-emitting units of a same color.

According to an implementation of the present disclosure, a partition structure is provided between two adjacent first quantum dot light-emitting units in a same column, and at least a part of film layers of a first quantum dot tandem layer extend to the partition structure and are at least partially broken at the partition structure; and/or
wherein a partition structure is provided between two adjacent second quantum dot light-emitting units in a same column, and at least a part of film layers of a second quantum dot tandem layer extend to the partition structure and are at least partially broken at the partition structure.

According to an implementation of the present disclosure, the first quantum dot tandem layer includes a first quantum dot material layer and a first electron transport layer which are stacked, the first electron transport layer includes first zinc oxide nanoparticles doped with a metal, the first zinc oxide nanoparticles are cross-linked through a first organic matter, and the first quantum dot material layer includes quantum dots cross-linked through a second organic matter.

According to an implementation of the present disclosure, the first quantum dot light-emitting unit further includes a charge generation layer between adjacent first quantum dot tandem layers, and the charge generation layer includes an N-type charge generation layer arranged adjacent to the first electron transport layer;
wherein the N-type charge generation layer includes second zinc oxide nanoparticles, an amount of a metal doped in the second zinc oxide nanoparticles is smaller than an amount of the metal doped in the first zinc oxide nanoparticles or the second zinc oxide nanoparticles are not doped with a metal, and the second zinc oxide nanoparticles are cross-linked through a third organic matter.

According to an implementation of the present disclosure, the first electron transport layer is at a side of the first quantum dot material layer away from the base substrate;
wherein the first quantum dot light-emitting unit further includes a charge generation layer between adjacent first quantum dot tandem layers, and the charge generation layer includes a P-type charge generation layer and an N-type charge generation layer stacked in sequence at a side of the first electron transport layer away from the base substrate;
wherein roughness of a surface of the N-type charge generation layer away from the base substrate is greater than roughness of a surface of the P-type charge generation layer away from the base substrate.

According to an implementation of the present disclosure, the charge generation layer includes at least one N-type charge generation layer and a plurality of P-type charge generation layers, and the number of the P-type charge generation layers is greater than the number of the N-type charge generation layer;
wherein roughness of a surface of a P-type charge generation layer, which is the farthest from the N-type charge generation layer, away from the base substrate is smaller than roughness of a surface of the N-type charge generation layer away from the base substrate.

According to an implementation of the present disclosure, the first quantum dot tandem layer includes a first quantum dot material layer, a first protective layer and a first electron transport layer which are stacked in sequence, the first protective layer is arranged on a surface of the first quantum dot material layer away from the base substrate, and roughness of a surface of the first electron transport layer away from the base substrate is smaller than roughness of a surface of the first protective layer close to the base substrate.

According to an implementation of the present disclosure, a material of the first protective layer is an electron-transporting polymer or molybdenum oxide.

According to an implementation of the present disclosure, a thickness of the first protective layer does not exceed 10 nanometers.

According to an implementation of the present disclosure, the pixel layer further includes a pixel definition layer, the pixel definition layer having a first pixel opening exposing at least partial region of the first pixel electrode and a second pixel opening exposing at least partial region of the second pixel electrode, the first quantum dot tandem layer covers the first pixel electrode exposed by the first pixel opening, and the second quantum dot tandem layer covers the second pixel electrode exposed by the second pixel opening;
wherein in the display region of the display panel, roughness of a side surface and a top surface of the pixel definition layer is greater than roughness of surfaces of the first pixel electrode and the second pixel electrode.

According to an implementation of the present disclosure, the pixel layer includes a first part and a second part arranged side by side, and the first part and the second part are both provided with a quantum dot material layer;
wherein the pixel layer is further provided with a pixel electrode;
wherein an orthographic projection of the first part on the base substrate is located within an orthographic projection of the pixel electrode on the base substrate, and the first part is at a side of the pixel electrode away from the base substrate;
wherein an orthographic projection of the second part on the base substrate is located outside the orthographic projection of the pixel electrode on the base substrate;
wherein the number of quantum dot material layers included in at least a part of the first part is smaller than the number of quantum dot material layers included in at least a part of the second part.

According to an implementation of the present disclosure, a thickness of at least a part of the quantum dot material layers in the second part is smaller than a thickness of at least a part of the quantum dot material layers in the first part.

According to an implementation of the present disclosure, the first part includes a first quantum dot light-emitting unit and a second quantum dot light-emitting unit arranged side by side;
wherein the first quantum dot light-emitting unit includes a first pixel electrode, n first quantum dot tandem layers and a first common electrode stacked in sequence at a side of the base substrate, the second quantum dot light-emitting unit includes a second pixel electrode, m second quantum dot tandem layers and a second common electrode stacked in sequence at a side of the base substrate, and one quantum dot material layer is respectively provided in the first quantum dot tandem layers and the second quantum dot tandem layers;
wherein an light-emitting wavelength of the first quantum dot light-emitting unit is shorter than an light-emitting wavelength of the second quantum dot light-emitting unit;
wherein n and m are both positive integers greater than or equal to 1, and n>m.

According to a second aspect of the present disclosure, there is provided a display device including the display panel described above.

It is to be understood that the foregoing general description and the following detailed description are illustrative and explanatory only and are not restrictive of the present disclosure.

### BRIEF DESCRIPTION OF THE DRAWINGS

The accompanying drawings, which are incorporated into the specification and constitute a part of the specification, illustrate embodiments consistent with the present disclosure, and together with the specification serve to explain the principles of the present disclosure. Obviously, the accompanying drawings described below are only some embodiments of the present disclosure, and for those of ordinary skill in this art, other accompanying drawings can be obtained based on these accompanying drawings without creative work.

FIG. 1 is a schematic diagram of a top view of a structure of a display panel in an implementation of the present disclosure.

FIG. 2 is a schematic diagram of a cross-sectional view of a structure of a display panel in an implementation of the present disclosure.

FIG. 3 is a schematic diagram of a structure of a quantum dot light-emitting unit in an implementation of the present disclosure.

FIG. 4 is a schematic diagram of a structure of a quantum dot light-emitting unit in an implementation of the present disclosure.

FIG. 5 is a schematic diagram of a structure of a quantum dot light-emitting unit in an implementation of the present disclosure.

FIG. 6 is a schematic diagram of a partial cross-sectional view of a structure of a display panel in an implementation of the present disclosure.

FIG. 7 is a schematic diagram of a driving principle of a display panel in an implementation of the present disclosure.

FIG. 8 is a schematic diagram of a driving principle of a display panel in an implementation of the present disclosure.

FIG. 9 is a schematic diagram of a structure of a first quantum dot light-emitting unit in an implementation of the present disclosure.

FIG. 10 is a schematic diagram of a partial top view of a structure of a display panel in an implementation of the present disclosure.

FIG. 11 is a schematic diagram of a cross-sectional structure at D1-D2 in FIG. 10 in an implementation of the present disclosure.

FIG. 12 is a schematic diagram of a cross-sectional structure at D3-D4 in FIG. 10 in an implementation of the present disclosure.

FIG. 13 is a schematic diagram of a cross-sectional structure at D1-D2 in FIG. 10 in an implementation of the present disclosure.

FIG. 14 is a schematic diagram of a partial cross-sectional view of a structure of a display panel in an implementation of the present disclosure.

### DETAILED DESCRIPTION

Example implementations will now be described more fully with reference to the accompanying drawings. However, the example implementations can be implemented in a variety of forms and should not be construed as limited to the implementations set forth herein; rather, these implementations are provided so that the present disclosure will be comprehensive and complete and fully convey the concepts of the example implementations to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this specification to describe a relative relationship of a component shown in a drawing to another component, these terms are used in this specification only for convenience, for example, the terms are based on direction(s) of examples described in the drawings. It can be understood that if a device in a drawing is turned upside down, a component described as an “upper” component will become a “lower” component. When a structure is “on” another structure, it may mean that the structure is formed integrally on another structure, or that the structure is “directly” disposed on another structure, or that the structure is “indirectly” disposed on another structure through other structure(s).

The terms “one”, “a/an”, “the”, “said” and “at least one” are used to indicate the presence of one or more elements/components/etc. The terms “comprising/including” and “having” are used to express an open-ended inclusive meaning and mean that additional elements/components/etc. may exist in addition to the listed elements/components/etc. The terms “first”, “second” and “third” etc. are used merely as markers and are not intended to limit the quantity of associated objects.

In implementations of the present disclosure, a structure layer A being located at a side of a structure layer B away from a base substrate may be understood as: the structure layer A being formed at the side of the structure layer B away from the base substrate. When the structure layer B is a patterned structure, a part of the structure of the structure layer A may also be located at the same physical height as the structure layer B or lower than the physical height of the structure layer B, and the base substrate is a height reference.

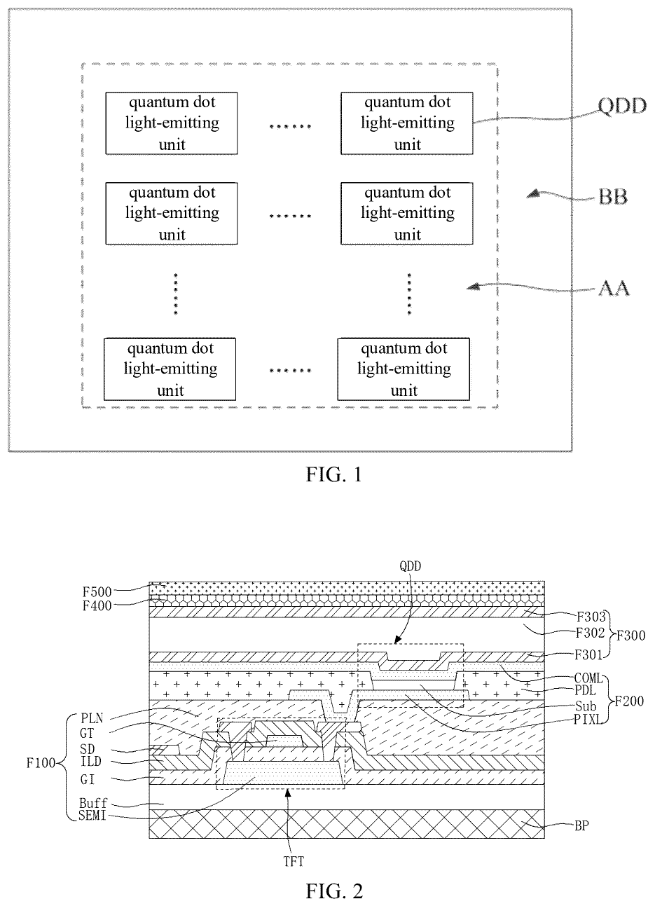

An implementation of the present disclosure provides a display panel. As shown in FIG. 1, the display panel includes a display region AA and a peripheral region BB located at at least one side of the display region AA. For example, the display panel includes a display region AA and a peripheral region BB surrounding the display region AA. In the display region AA, sub-pixels of a plurality of different colors are arranged, and at least a part of the sub-pixels are quantum dot light-emitting units QDD. The quantum dot light-emitting units QDD are quantum dot light-emitting diodes. For example, sub-pixels of a plurality of different colors are arranged in the display region AA, each of the sub-pixels is a quantum dot light-emitting unit QDD. The color of the light emitted by a quantum dot light-emitting unit QDD when emitting light is the color of the sub-pixel. In the implementation of the present disclosure, the color(s) of the sub-pixels in the display region AA includes(include) but not limited to one or more of the colors of green, blue, red, purple, cyan, yellow, magenta, etc. For example, in an example, as shown in FIG. 10, the display panel is provided with sub-pixels of three different colors in the display region AA, which are blue quantum dot light-emitting units B, green quantum dot light-emitting units G, and red quantum dot light-emitting units R.

FIG. 2 is a schematic diagram of a partial structure of a display panel in an implementation of the present disclosure. Referring to FIG. 2, the display panel includes a base substrate BP, a driving layer F100 and a pixel layer F200 which are stacked in sequence. The pixel layer is provided with respective quantum dot light-emitting units QDD in the display region AA. The driving layer is provided with pixel driving circuits corresponding to the respective quantum dot light-emitting units QDD in a one to one correspondence. Each quantum dot light-emitting unit QDD is controlled to emit light under driving of a corresponding pixel driving circuit. Of course, in the example of FIG. 2, the driving layer drives each quantum dot light-emitting unit QDD in an active driving manner. In other implementations of the present disclosure, the driving layer may also drive each quantum dot light-emitting unit QDD in a passive matrix driving manner, or a part of quantum dot light-emitting units QDD emit light under driving of a same pixel driving circuit.

In the example of FIG. 2, in the driving layer F100, any pixel driving circuit may include transistor(s) TFT and a storage capacitor. Further, a transistor TFT may be a thin film transistor, and the thin film transistor may be selected from a top-gate thin film transistor, a bottom-gate thin film transistor or a double-gate thin film transistor. The material of an active layer of the thin film transistor may be an amorphous silicon semiconductor material, a low-temperature polycrystalline silicon semiconductor material, a metal oxide semiconductor material, an organic semiconductor material or other type(s) of semiconductor material. The thin film transistor may be an N-type thin film transistor or a P-type thin film transistor.

It is understandable that, among the transistor(s) in a pixel driving circuit, the types of any two transistors may be the same or different. As an example, in an implementation, in a pixel driving circuit, a part of transistors may be N-type transistors and a part of the transistors may be P-type transistors. As another example, in another implementation of the present disclosure, in a pixel driving circuit, the material of the active layers of a part of transistors may be a low-temperature polysilicon semiconductor material, and the material of the active layers of a part of the transistors may be a metal oxide semiconductor material. In some implementations of the present disclosure, the thin film transistors are low-temperature polysilicon transistors. In some other implementations of the present disclosure, a part of the thin film transistors are low-temperature polysilicon transistors, and a part of the thin film transistors are metal oxide transistors.

Optionally, the driving layer F100 may include a semiconductor layer SEMI, a gate insulation layer GI, a gate layer GT, an interlayer dielectric layer ILD, a source-drain metal layer SD, a planarization layer PLN, etc., which are stacked between the base substrate BP and the pixel layer F200. Each thin film transistor and a storage capacitor may be formed by film layers such as a semiconductor layer SEMI, a gate insulation layer GI, a gate layer GT, an interlayer dielectric layer ILD, a source-drain metal layer SD, etc. A positional relationship between film layers may be determined according to a film layer structure of a thin film transistor. Further, the semiconductor layer SEMI may be used to form a channel region of the transistor, and may also be formed as a part of a line or a conductive structure by conductorization when necessary. The gate layer may be used to form one or more of gate layer lines such as a scan line, a reset control line, a light-emitting control line, etc., or may also be used to form a gate of the transistor, or may also be used to form a part or all of an electrode plate of the storage capacitor. The source-drain metal layer may be used to form a source-drain metal layer line such as a data voltage line, a power supply voltage line, etc., or may also be used to form a part of an electrode plate of the storage capacitor. Of course, in other implementations of the present disclosure, the driving layer F100 may further include other film layers as required. For example, the driving layer F100 may further include a light shielding layer between the semiconductor layer SEMI and the base substrate BP. As required, any of the above-mentioned film layers such as the semiconductor layer SEMI, the gate layer GT, the source-drain metal layer SD, etc. may also be multilayered. For example, the driving layer F100 may include two different semiconductor layers SEMI, or two or three source-drain metal layers SD, or two or three gate layers GT; accordingly, the insulation film layers in the driving layer F100 (such as the gate insulation layer GI, the interlayer dielectric layer ILD, the planarization layer PLN, etc.) may be adaptively increased or decreased.

As an example, referring to FIG. 2, the driving layer F100 may include an inorganic buffer layer Buff, a semiconductor layer SEMI, a gate insulation layer GI, a gate layer GT, an interlayer dielectric layer ILD, a source-drain metal layer SD and a display panel stacked in sequence, and a thin film transistor formed in this way is a top-gate thin film transistor.

In the example of FIG. 2, the pixel layer F200 may be arranged at a side of the driving layer F100 away from the base substrate BP, and may include a pixel electrode layer PIXL, a pixel definition layer PDL, a quantum dot tandem layer Sub, and a common electrode layer COML that are stacked in sequence. The pixel electrode layer PIXL has a plurality of pixel electrodes in the display region of the display panel. The pixel definition layer PDL has a plurality of through pixel openings that correspond to the plurality of pixel electrodes in the display region in a one-to-one correspondence. Any one of the pixel openings exposes at least partial region of a corresponding pixel electrode. The quantum dot tandem layer Sub at least covers a pixel electrode exposed by the pixel definition layer PDL. The common electrode layer COML may cover the quantum dot tandem layer Sub in the display region. In this way, the pixel electrode, the common electrode layer COML, and the quantum dot tandem layer Sub between the pixel electrode and the common electrode layer COML form a quantum dot light-emitting unit QDD.

In some examples, the pixel layer F200 may further include a light extraction layer at a side of the common electrode layer COML away from the base substrate BP to enhance the light extraction efficiency of the quantum dot light-emitting unit QDD.

In some examples, referring to FIG. 2, the display panel may further include a thin film encapsulation layer F300. The thin film encapsulation layer F300 is arranged on a surface of the pixel layer F200 away from the base substrate BP, and may include inorganic encapsulation layer(s) and organic encapsulation layer(s) alternately stacked. A touch layer is arranged at a side of the thin film encapsulation layer F300 away from the base substrate BP. The inorganic encapsulation layer(s) may effectively block external moisture and oxygen, and prevent water and oxygen from invading the quantum dot tandem layer Sub and causing material degradation. Optionally, the edge(s) of the inorganic encapsulation layer(s) may be located in the peripheral region. An organic encapsulation layer is located between two adjacent inorganic encapsulation layers to achieve planarization and reduce the stress between the inorganic encapsulation layers. The edge of the organic encapsulation layer may be located between the edge of the display region and the edge(s) of the inorganic encapsulation layer(s). As an example, the thin film encapsulation layer F300 includes a first inorganic encapsulation layer F301, an organic encapsulation layer F302, and a second inorganic encapsulation layer F303 stacked in sequence at a side of the pixel layer F200 away from the base substrate BP.

In some examples, the display panel may further include a touch layer F400. The touch layer F400 is arranged at a side of the thin film encapsulation layer F300 away from the base substrate BP for implementing a touch operation of the display panel.

In some examples, the display panel may further include a reflection reduction layer F500. The reflection reduction layer F500 may be arranged at a side of the thin film encapsulation layer F300 away from the pixel layer F200 to reduce reflection of ambient light by the display panel, thereby reducing the impact of the ambient light on the display effect.

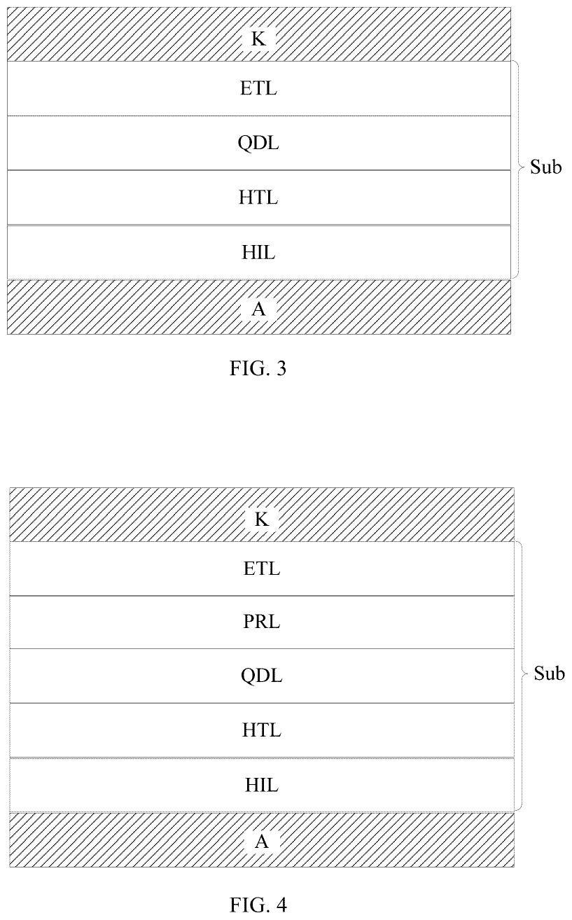

In implementations of the present disclosure, referring to FIG. 3 to FIG. 5, a quantum dot light-emitting unit QDD may be provided with one quantum dot tandem layer Sub, or may be provided with a plurality of stacked quantum dot tandem layers Sub, where each quantum dot tandem layer Sub is provided with a quantum dot material layer QDL.

FIG. 3 illustrates a schematic diagram of a structure of a quantum dot light-emitting unit QDD. In the example of FIG. 3, the quantum dot light-emitting unit QDD has one quantum dot tandem layer Sub. Referring to FIG. 3, the quantum dot light-emitting unit QDD includes an anode A, a quantum dot tandem layer Sub, and a cathode K stacked in sequence. The quantum dot tandem layer Sub includes a hole regulation layer, a quantum dot material layer QDL, and an electron regulation layer stacked in sequence, the hole regulation layer is located at a side of the quantum dot material layer QDL close to the anode A, and the electron regulation layer is located at a side of the quantum dot material layer QDL close to the cathode K. The anode A is used to inject holes into the quantum dot material layer QDL through the hole regulation layer, and the cathode K is used to inject electrons into the quantum dot material layer QDL through the electron regulation layer. The hole regulation layer and the electron regulation layer are respectively used to regulate the injection efficiency and injection speed of holes and electrons injected into the quantum dot material layer QDL, and to regulate the energy levels of the injected electrons and holes, so as to improve the balance between hole injection and electron injection, and thus improve the performance of the quantum dot light-emitting unit QDD, such as one or more of: improving the light-emitting efficiency of the quantum dot light-emitting unit QDD, improving the device lifespan of the quantum dot light-emitting unit QDD, reducing the power supply voltage of the quantum dot light-emitting unit QDD, etc.

The hole regulation layer may include one or more of the film layers such as a hole injection layer HIL, a hole transport layer HTL, an electron blocking layer, etc. The hole injection layer HIL, the hole transport layer HTL, the electron blocking layer, etc. are stacked in sequence along a direction from the anode A to the quantum dot material layer QDL. It is understood that in some examples, one or more of the film layers such as the hole injection layer HIL, the hole transport layer HTL, the electron blocking layer, etc. may be set as a multi-layer stacked structure. For example, the hole transport layer HTL may include a first kind of hole transport layer and a second kind of hole transport layer, etc., which are stacked. In an example, the hole regulation layer includes a hole injection layer HIL and a hole transport layer HTL which are stacked, and the hole injection layer HIL, the hole transport layer HTL and the quantum dot material layer QDL are stacked in sequence.

The electron regulation layer may include one or more of film layers such as an electron injection layer, an electron transport layer ETL, a hole blocking layer, etc. The electron injection layer, the electron transport layer ETL, the hole blocking layer, etc. are stacked in sequence along a direction from the cathode K to the quantum dot material layer QDL. It is understood that in some examples, one or more of film layers such as the electron injection layer, the electron transport layer ETL, the hole blocking layer, etc. may be set as a multi-layer stacked structure. For example, the electron transport layer ETL may include a first kind of electron transport layer and a second kind of electron transport layer, etc. which are stacked. In an example, the electron regulation layer includes an electron transport layer ETL.

In some implementations of the present disclosure, referring to FIG. 4, the electron regulation layer may further include a protective layer PRL adjacent to the quantum dot material layer QDL. The protective layer PRL may have an electron transport capability and is used to protect the quantum dot material layer QDL, so as to avoid damage to the quantum dot material layer QDL during the preparation of the quantum dot light-emitting unit QDD. For example, the electron regulation layer may include a protective layer PRL and an electron transport layer ETL, and the quantum dot material layer QDL, the protective layer PRL and the electron transport layer ETL are stacked in sequence.

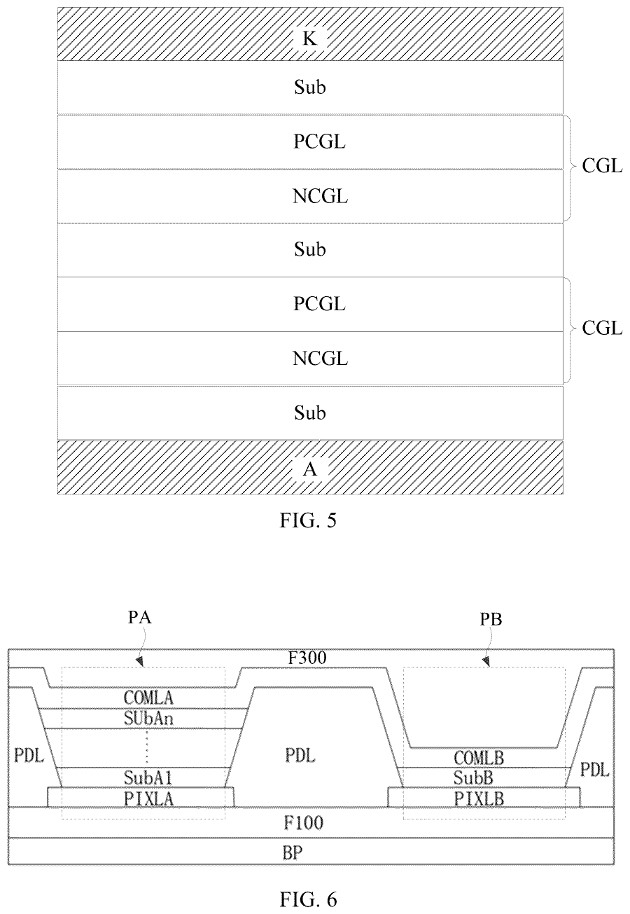

FIG. 5 illustrates a schematic diagram of the structure of another quantum dot light-emitting unit QDD. In the example of FIG. 5, the quantum dot light-emitting unit QDD has a plurality of stacked quantum dot tandem layers Sub. Referring to FIG. 5, the quantum dot light-emitting unit QDD includes an anode A, a plurality of stacked quantum dot tandem layers Sub, and a cathode K which are stacked in sequence. Any one of the quantum dot tandem layers Sub includes a hole regulation layer, a quantum dot material layer QDL, and an electron regulation layer stacked in sequence. The hole regulation layer is located at a side of the quantum dot material layer QDL close to the anode A, and the electron regulation layer is located at a side of the quantum dot material layer QDL close to the cathode K.

Optionally, the quantum dot light-emitting unit QDD may further include a charge generation layer CGL located between two adjacent quantum dot tandem layers Sub to improve the efficiency of injecting electrons and holes into the two adjacent quantum dot tandem layers Sub. For example, the charge generation layer CGL includes an N-type charge generation layer NCGL and a P-type charge generation layer PCGL stacked between two adjacent quantum dot tandem layers Sub. The N-type charge generation layer NCGL is arranged adjacent to the electron regulation layer of one of the quantum dot tandem layers Sub, and is used to inject electrons into the electron regulation layer of the quantum dot tandem layer Sub; and the P-type charge generation layer PCGL is arranged adjacent to the hole regulation layer of the other of the quantum dot tandem layers Sub, and is used to inject holes into the hole regulation layer of the quantum dot tandem layer Sub. Of course, it can be understood that in other examples, the charge generation layer CGL may also include other structure(s).

In an example, the N-type charge generation layer NCGL is arranged adjacent to the electron transport layer ETL, and the materials are substantially the same. The difference between the N-type charge generation layer NCGL and the electron transport layer ETL is that a doping amount of a doping material (a material with less mass content) in the N-type charge generation layer NCGL is lower than a doping amount of a doping material in the electron transport layer ETL. Alternatively, the materials of the N-type charge generation layer NCGL and the electron transport layer ETL may also be the same. For example, the material of the electron transport layer ETL includes zinc oxide doped with a low work function metal, such as zinc oxide doped with magnesium (mass content is 10% to 20%); the N-type charge generation layer NCGL may also include zinc oxide doped with a low work function metal, but the doping amount of the doped metal is lower than that of the electron transport layer ETL, or the low work function metal is not doped. For example, in the zinc oxide of the N-type charge generation layer NCGL, the mass content of the doped low work function metal is 0% to 10%, for example, 0%, 2%, 4%, 6%, 8% or 10%. The mass content of the low work function metal doped in the zinc oxide of the electron transport layer ETL is 10%, 12%, 14%, 16%, 18% or 20%.

This makes the energy level of the N-type charge generation layer NCGL more matched with the electron transport layer ETL, which is beneficial to improve the efficiency of the N-type charge generation layer NCGL injecting electrons into the electron transport layer ETL. In the implementation of the present disclosure, a metal with a work function smaller than 4.1 eV is used as a low work function metal.

In an example, the P-type charge generation layer PCGL is arranged adjacent to the hole injection layer HIL, and the materials are substantially the same. For example, the material of the P-type charge generation layer PCGL is the same as the material of the hole injection layer HIL, or the doping amount of the doping material in the material of the P-type charge generation layer PCGL is lower than the doping amount of the doping material in the material of the hole injection layer HIL. For example, the materials of the P-type charge generation layer PCGL and the hole injection layer HIL are both PEDOT:PSS or HAT-CN. For another example, the material of the hole injection layer HIL is one of oxides such as molybdenum oxide or nickel oxide, and may be doped with a high work function metal, for example being doped with aluminum. The material of the P-type charge generation layer PCGL is one of oxides such as molybdenum oxide or nickel oxide, and the content of the doped high work function metal is smaller than that of the hole transport layer HTL, or it is not doped with a high work function metal. In the implementation of the present disclosure, a metal having a work function of not smaller than 4.1 eV is used as a high work function metal.

In the quantum dot light-emitting unit QDD of the implementation of the present disclosure, film layers such as the hole regulation layer, the electron regulation layer, the charge generation layer CGL, etc. are used to provide electrons and holes to the quantum dot material layer QDL, so that the quantum dot material layer QDL can emit light. In the implementation of the present disclosure, the film layers such as the hole regulation layer, the electron regulation layer and the charge generation layer CGL, etc. can be called charge layers.

However, in the related art, the lifespans of quantum dot light-emitting units of different colors vary greatly, making it difficult to achieve a balance in lifespans of sub-pixels of different colors. For example, in the related art, the lifespan of a blue quantum dot light-emitting unit B is much lower than that of a green quantum dot light-emitting unit G and a red quantum dot light-emitting unit R.

In an implementation of the present disclosure, referring to FIG. 6 and FIG. 14, the pixel layer includes at least two regions, the two regions are provided with quantum dot material layer(s) QDL. The number of quantum dot material layer(s) QDL provided in one of the regions is greater than the number of quantum dot material layer(s) QDL provided in another one of the regions. The display panel of this implementation can achieve the balance of the lifespans of different quantum dot light-emitting units, or can be a product formed for balancing the lifespans of different quantum dot light-emitting units.

In some implementations of the present disclosure, referring to FIG. 6, the pixel layer includes a first quantum dot light-emitting unit PA and a second quantum dot light-emitting unit PB arranged side by side. The first quantum dot light-emitting unit PA includes a first pixel electrode PIXLA, n first quantum dot tandem layers SubA (stacked from the first-layer first quantum dot tandem layer SubA1 to the n^{th}-layer first quantum dot tandem layer SubAn) and a first common electrode COMLA stacked sequentially at a side of the base substrate BP. The second quantum dot light-emitting unit PB includes a second pixel electrode PIXLB, m second quantum dot tandem layer(s) SubB (only one layer is illustrated in FIG. 6) and a second common electrode COMLB stacked sequentially at a side of the base substrate BP. A layer of quantum dot material layer QDL is respectively arranged in the first quantum dot tandem layers SubA and the second quantum dot tandem layer SubB. A light-emitting wavelength of the first quantum dot light-emitting unit PA is shorter than a light-emitting wavelength of the second quantum dot light-emitting unit PB. In this example, n and m are both positive integers greater than or equal to 1, and n>m. In the example of FIG. 6, m=1. It can be understood that in other implementations of the present disclosure, m may be 2 or other positive integer(s). In the implementation, the first common electrode COMLA and the second common electrode COMLB may be parts of a common electrode layer COML, that is, both are located in the same whole electrode. Of course, in other implementations of the present disclosure, the first common electrode COMLA and the second common electrode COMLB may also be two independent electrodes.

The light-emitting wavelength of the first quantum dot light-emitting unit PA is shorter than the light-emitting wavelength of the second quantum dot light-emitting unit PB, which easily leads to the problem that the device lifespan of the first quantum dot light-emitting unit PA is shorter than that of the second quantum dot light-emitting unit PB. This implementation reduces the light-emitting brightness of a single quantum dot tandem layer Sub by making the number of quantum dot tandem layer(s) Sub provided in the first quantum dot light-emitting unit PA greater than that of the second quantum dot light-emitting unit PB, thereby extending the device lifespan of the first quantum dot light-emitting unit PA, and facilitating the lifespan balance between the first quantum dot light-emitting unit PA and the second quantum dot light-emitting unit PB. In the display panel, for each additional quantum dot tandem layer Sub in the quantum dot light-emitting unit QDD, additional process(processes) and cost(s) are required. In this implementation, while increasing the number of first quantum dot tandem layers SubA in the first quantum dot light-emitting unit PA, the number of second quantum dot tandem layer(s) SubB in the second quantum dot light-emitting unit PB is avoided to be increased synchronously, which can improve the lifespan balance between the first quantum dot light-emitting unit PA and the second quantum dot light-emitting unit PB while avoiding an increase in the cost of the display panel.

It is understandable that the light-emitting wavelength of the first quantum dot light-emitting unit PA is shorter than the light-emitting wavelength of the second quantum dot light-emitting unit PB, which indicates that the particle size of the quantum dot(s) in the first quantum dot light-emitting unit PA is smaller. Therefore, the display panel of the implementation of the present disclosure may also present the following features: the particle size of the quantum dot(s) in the first quantum dot light-emitting unit PA is smaller than the particle size of the quantum dot(s) in the second quantum dot light-emitting unit PB; the number of quantum dot material layer(s) in the first quantum dot light-emitting unit PA is greater than the number of quantum dot material layer(s) in the second quantum dot light-emitting unit PB.

In an implementation of the present disclosure, the first quantum dot light-emitting unit PA is a blue quantum dot light-emitting unit, and the second quantum dot light-emitting unit PB includes two kinds of different quantum dot light-emitting units QDD, such as a red quantum dot light-emitting unit and a green quantum dot light-emitting unit, etc. Generally, the lifespan of a blue quantum dot light-emitting unit is significantly different from that of a red quantum dot light-emitting unit and a green quantum dot light-emitting unit. In this example, by providing a plurality of first quantum dot tandem layers SubA, the light-emitting brightness of a single first quantum dot tandem layer SubA can be reduced, thereby increasing the lifespan of each first quantum dot tandem layer SubA, and accordingly achieving the purpose of increasing the device lifespan of the first quantum dot light-emitting unit PA. This can significantly reduce the difference in lifetime between the first quantum dot light-emitting unit PA and the second quantum dot light-emitting unit PB.

In an implementation of the present disclosure, n is greater than m by 1 or 2. In this way, the first quantum dot light-emitting unit PA can have more quantum dot tandem layers Sub to improve the device lifespan of the first quantum dot light-emitting unit PA, and the display panel performance can be prevented from being unstable due to the large difference in the number of quantum dot tandem layer(s) Sub between the first quantum dot light-emitting unit PA and the second quantum dot light-emitting unit PB, for example, the common electrode layer COML can be prevented from being partially broken due to the large step difference between the first common electrode COMLA and the second common electrode COMLB.

In an implementation of the present disclosure, a step difference between a surface of the first quantum dot light-emitting unit PA away from the base substrate BP and a surface of the second quantum dot light-emitting unit PB away from the base substrate BP does not exceed 400 nm. In this way, the step difference between the first common electrode COMLA and the second common electrode COMLB can be made to be no more than 400 nm, thereby avoiding local breakage in the common electrode layer COML and affecting the uniformity of the voltage on the common electrode layer COML. It can be understood that compared with the first common electrode COMLA, the second common electrode COMLB is closer to the base substrate BP.

In an implementation of the present disclosure, m may be 1. In other words, the second quantum dot light-emitting unit PB includes only one second quantum dot tandem layer SubB. In this way, it is possible to avoid increased cost due to a plurality of stacked second quantum dot tandem layers SubB being provided in the second quantum dot light-emitting unit PB. Thus, this implementation can reduce the cost of the display panel while the lifespan of the second quantum dot light-emitting unit PB meets the requirements of the display panel.

In an implementation of the present disclosure, the display panel further includes a thin film encapsulation layer F300 located at a side of the pixel layer away from the base substrate BP. The thin film encapsulation layer F300 may cover the pixel layer to isolate water and oxygen and improve the stability of the quantum dot light-emitting unit QDD. Referring to FIG. 6, the thickness of a part of the thin film encapsulation layer F300 that overlaps with the first quantum dot light-emitting unit PA is smaller than the thickness of a part of the thin film encapsulation layer F300 that overlaps with the second quantum dot light-emitting unit PB. In this example, the part of the thin film encapsulation layer F300 overlapping with the second quantum dot light-emitting unit PB has a larger thickness, which can facilitate the preparation of the thin film encapsulation layer F300. For example, a thin film encapsulation layer F300 having a substantially flat upper surface (a surface away from the base substrate BP) can be prepared, thereby avoiding the increase in cost and processes caused by additional patterning of the thin film encapsulation layer F300. In addition, the thickness of the part of the thin film encapsulation layer F300 overlapping with the first quantum dot light-emitting unit PA is smaller, which is beneficial to increase the light output efficiency of the first quantum dot light-emitting unit PA, and further helps to further reduce the brightness of each first quantum dot tandem layer SubA in the first quantum dot light-emitting unit PA and extend the device lifespan of the first quantum dot light-emitting unit PA.

In an implementation of the present disclosure, the second quantum dot light-emitting unit PB includes a quantum dot light-emitting unit QDD of one color, or includes quantum dot light-emitting units QDD of multiple different colors. The area ratio of the first quantum dot light-emitting unit PA is greater than the area ratio of a quantum dot light-emitting unit QDD of any color in the second quantum dot light-emitting unit PB. For example, the aperture ratio of the first quantum dot light-emitting unit PA is greater than the aperture ratio of any other quantum dot light-emitting unit QDD. In this way, the aperture ratio of the first quantum dot light-emitting unit PA is larger and the light-emitting brightness can be reduced, thereby further extending the device lifespan of the first quantum dot light-emitting unit PA.

In this implementation, the area ratio of the first quantum dot light-emitting unit(s) PA can be increased by increasing the number of first quantum dot light-emitting unit(s) PA, or by increasing the size of the first quantum dot light-emitting unit(s) PA, or the area ratio of the first quantum dot light-emitting unit(s) PA can also be increased by increasing the size of the first quantum dot light-emitting unit(s) PA and the number of the first quantum dot light-emitting unit(s) PA at the same time, or other methods can be used to increase the area ratio of the first quantum dot light-emitting unit(s) PA. For example, in a feasible example, the size of a first quantum dot light-emitting unit PA is larger than the size of a second quantum dot light-emitting unit PB of any color, and the number of quantum dot light-emitting units QDD of different colors is the same. For another example, in a feasible example, the number of first quantum dot light-emitting units PA is twice the number of quantum dot light-emitting unit(s) QDD of any other color, or more.

In an implementation of the present disclosure, when a pixel driving circuit drives a quantum dot light-emitting unit QDD to emit light, it is needed to apply voltages on two electrodes of the quantum dot light-emitting unit QDD respectively to overcome a voltage drop of the quantum dot light-emitting unit QDD and ensure that a driving current flows through the quantum dot light-emitting unit QDD. The more layers of quantum dot tandem layers Sub included in the quantum dot light-emitting unit QDD, the greater the voltage required when the quantum dot light-emitting unit QDD is started. In the example of FIG. 6, the first common electrode COMLA and the second common electrode COMLB of the first quantum dot light-emitting unit PA and the second quantum dot light-emitting unit PB are both part of an entire electrode and are applied with the same voltage, and the first pixel electrode PIXLA and the second pixel electrode PIXLB are respectively applied with their own power supply voltages.

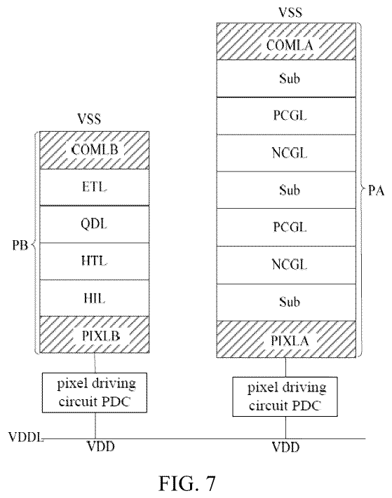

In some implementations of the present disclosure, referring to FIG. 7, the display panel may be provided with a power supply voltage line VDDL in the display region AA, for example, a gridded power supply voltage line VDDL is provided, and the power supply voltage line VDDL is used to apply a power supply voltage VDD. The common electrode layers of the quantum dot light-emitting unit QDD are electrically connected to each other to form a whole electrode, and are used to apply a reference power supply voltage VSS. The pixel electrode of the quantum dot light-emitting unit QDD is electrically connected to the power supply voltage line VDDL through a corresponding pixel driving circuit PDC. For example, the first common electrode COMLA of the first quantum dot light-emitting unit PA and the second common electrode COMLB of the second quantum dot light-emitting unit PB are all applied with the reference power supply voltage VSS, and the first pixel electrode PIXLA of the first quantum dot light-emitting unit PA and the second pixel electrode PIXLB of the second quantum dot light-emitting unit PB are respectively connected to the power supply voltage line VDDL through their respective corresponding pixel driving circuits PDC. A pixel driving circuit PDC can control the electrical conduction and cutoff between a quantum dot light-emitting unit QDD and a power supply voltage line VDDL, and control a current flowing through the quantum dot light-emitting unit QDD, thereby controlling whether the quantum dot light-emitting unit QDD emits light and controlling the light-emitting brightness. In this example, the voltage differences between both sides of the first quantum dot light-emitting unit PA and the second quantum dot light-emitting unit PB are the same, which makes the layout of the power supply voltage line VDDL of the display panel simpler and requires fewer power signals. However, the first quantum dot light-emitting unit PA has a larger number of quantum dot tandem layers Sub and a high turn-on voltage is needed. For example, the turn-on voltage of a first quantum dot light-emitting unit PA with two quantum dot tandem layers Sub may reach 7~8V or higher. The second quantum dot light-emitting unit PB has a smaller number of quantum dot tandem layer(s) Sub and a small turn-on voltage is needed. For example, the turn-on voltage of a second quantum dot light-emitting unit PB with a single quantum dot tandem layer Sub is in the range of 4~5V. In order to enable the first quantum dot light-emitting unit PA to emit light normally, the voltage difference between the power supply voltage VDD and the reference power supply voltage VSS is not smaller than the turn-on voltage of the first quantum dot light-emitting unit PA. This makes the voltage of the power supply voltage VDD relative high. For the second quantum dot light-emitting unit PB, the voltage difference between the power supply voltage VDD and the reference power supply voltage VSS significantly exceeds its own turn-on voltage. Therefore, the voltage difference between two sides of the second quantum dot light-emitting unit PB has room for decrease, which makes the power consumption and lifespan of the second quantum dot light-emitting unit PB have room for improvement.

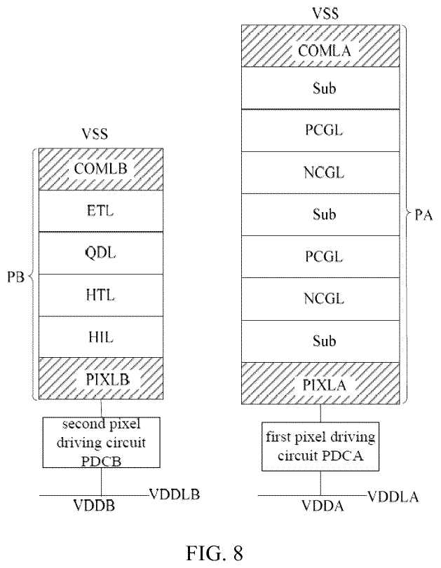

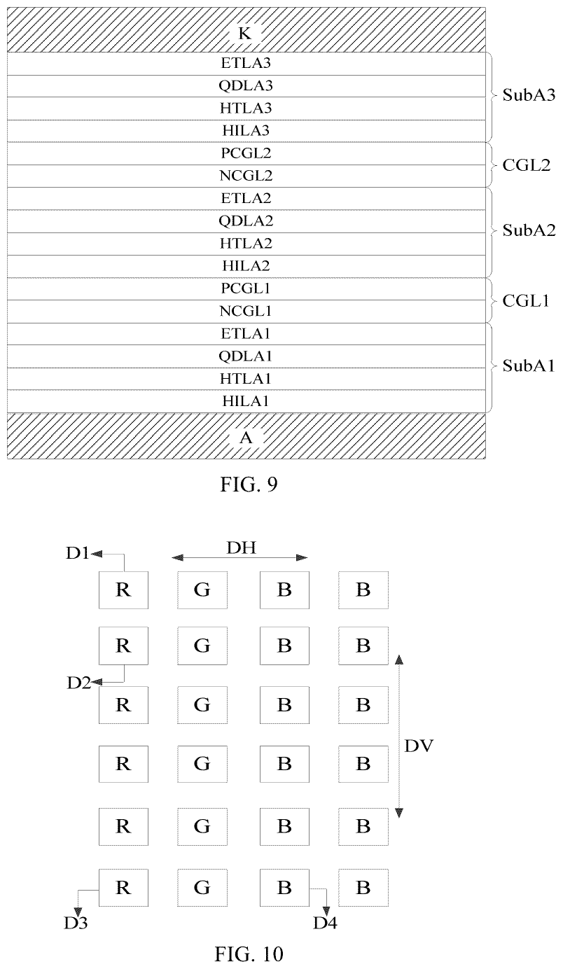

In some other implementations of the present disclosure, the display panel may provide different power supply voltages for the first quantum dot light-emitting unit PA and the second quantum dot light-emitting unit PB, respectively, so that the power supply voltages and the turn-on voltages of the quantum dot light-emitting units QDD match each other, which is beneficial to reducing power consumption and improving the lifespans of the quantum dot light-emitting units QDD. For example, referring to FIG. 8, the driving layer has a first pixel driving circuit PDCA configured to drive the first quantum dot light-emitting unit PA and a second pixel driving circuit PDCB configured to drive the second quantum dot light-emitting unit PB, and the driving layer includes a first power supply voltage line VDDLA connected to the first pixel driving circuit PDCA and a second power supply voltage line VDDLB connected to the second pixel driving circuit PDCB. The first pixel electrode PIXLA is electrically connected to the first power supply voltage line VDDLA through the first pixel driving circuit PDCA. The first quantum dot light-emitting unit PA is configured to emit light under driving of a driving current between the first power supply voltage line VDDLA and the first common electrode COMLA. The second pixel electrode PIXLB is electrically connected to the second power supply voltage line VDDLB through the second pixel driving circuit PDCB. The second quantum dot light-emitting unit PB is configured to emit light under driving of a driving current between the second power supply voltage line VDDLB and the second common electrode COMLB. The first power supply voltage line VDDLA and the second power supply voltage line VDDLB can be applied with different power supply voltages, respectively. Specifically, when driving the display panel, a voltage difference between a first power supply voltage VDDA applied on the first power supply voltage line VDDLA and the reference power supply voltage VSS applied on the first common electrode COMLA may be greater than a voltage difference between a second power supply voltage VDDB applied on the second power supply voltage line VDDLB and the reference power supply voltage VSS applied on the second common electrode COMLB. In this implementation, the first quantum dot light-emitting unit PA and the second quantum dot light-emitting unit PB are driven by different power supply voltages, respectively, so that the power supply voltages match the turn-on voltages of the quantum dot light-emitting units QDD, avoiding a reduction in the lifespans of the quantum dot light-emitting units QDD and excessive power consumption due to an over high power supply voltage, and can ensure the device lifespan of the second quantum dot light-emitting unit PB under the premise of reducing the power consumption of the display panel.

In an example, compared to the reference power voltage VSS, the first power voltage VDDA and the second power voltage VDDB are high-level voltages; the first power voltage VDDA may be greater than the second power voltage VDDB.

In an example, the width of the first power supply voltage line VDDLA is greater than the width of the second power supply voltage line VDDLB. Since the voltage of the first power supply voltage VDDA applied on the first power supply voltage line VDDLA is higher, the first power supply voltage line VDDLA faces a greater voltage drop when distributing the first power supply voltage VDDA. In this feasible solution, the increase in the width of the first power supply voltage line VDDLA can reduce the voltage drop when distributing the first power supply voltage VDDA, thereby improving the uniformity of the first power supply voltage VDDA on the display panel.

In some implementations of the present disclosure, the quantum dot light-emitting units QDD of the display panel may be mainly prepared by a solution-based method (such as a screen printing process, an inkjet printing process, a coating process, etc.). In the preparation procedure, quantum dot light-emitting units QDD of different colors may be prepared separately, or may be prepared at the same time, or may share a part of the preparation processes.

In the following, taking a preparation procedure of a kind of first quantum dot light-emitting unit PA as an example, the materials, preparation processes, etc. of film layers of the first quantum dot light-emitting unit PA are illustratively described. In this example, the first quantum dot light-emitting unit PA is a normal structure. Specifically, the first pixel electrode PIXLA is the anode A of the first quantum dot light-emitting unit PA, and the first common electrode COMLA is the cathode K of the first quantum dot light-emitting unit PA. It can be understood that the preparation process(processes) and materials of the first quantum dot light-emitting unit PA in the following example can be adapted to be suitable for an inverted structure (the first pixel electrode PIXLA is the cathode, and the first common electrode COMLA is the anode) after adaptive adjustment.

In the example of the first quantum dot light-emitting unit PA of the normal structure, the first quantum dot light-emitting unit PA includes an anode A, a first-layer first quantum dot tandem layer SubA1, a first charge generation layer CGL1, a second-layer first quantum dot tandem layer SubA2, a second charge generation layer CGL2, a third-layer first quantum dot tandem layer SubA3 and a cathode K, which are stacked in sequence. The anode is the first pixel electrode PIXLA, and the cathode is the second common electrode COMLB. In this example, the first quantum dot light-emitting unit PA has three first quantum dot tandem layers SubA. It can be understood that the materials and preparation methods of this example can be adaptively adjusted and applied to a first quantum dot light-emitting unit PA having other numbers of layers of first quantum dot tandem layers SubA, for example, it is also applicable to a first quantum dot light-emitting unit PA having two layers of first quantum dot tandem layers SubA.

In this example, any one first quantum dot tandem layer SubA includes a first hole injection layer, a first hole transport layer, a first quantum dot material layer, and a first electron transport layer, which are stacked in sequence. For example, the first-layer first quantum dot tandem layer SubA1 includes a first-layer first hole injection layer HILA1, a first-layer first hole transport layer HTLA1, a first-layer first quantum dot material layer QDLA1, and a first-layer first electron transport layer ETLA1, which are stacked in sequence. The second-layer first quantum dot tandem layer SubA2 includes a second-layer first hole injection layer HILA2, a second-layer first hole transport layer HTLA2, a second-layer first quantum dot material layer QDLA2, and a second-layer first electron transport layer ETLA2, which are stacked in sequence. The third-layer first quantum dot tandem layer SubA3 includes a third-layer first hole injection layer HILA3, a third-layer first hole transport layer HTLA3, a third-layer first quantum dot material layer QDLA3, and a third-layer first electron transport layer ETLA3, which are stacked in sequence.

In this example, any one layer of charge generation layer CGL includes an N-type charge generation layer NCGL and a P-type charge generation layer PCGL which are stacked in sequence. The N-type charge generation layer NCGL is arranged adjacent to a first electron transport layer of an adjacent first quantum dot tandem layer SubA, and the P-type charge generation layer PCGL is arranged adjacent to a first hole injection layer of the adjacent first quantum dot tandem layer SubA. For example, the first charge generation layer CGL1 includes a first N-type charge generation layer NCGL1 and a first P-type charge generation layer PCGL1 which are stacked. The first N-type charge generation layer NCGL1 is arranged adjacent to the first-layer first electron transport layer ETLA1, and the first P-type charge generation layer PCGL1 is arranged adjacent to the second-layer first hole injection layer HILA2. The second charge generation layer CGL2 includes a second N-type charge generation layer NCGL2 and a second P-type charge generation layer PCGL2 which are stacked. The second N-type charge generation layer NCGL2 is arranged adjacent to the second-layer first electron transport layer ETLA2, and the second P-type charge generation layer PCGL2 is arranged adjacent to the third-layer first hole injection layer HILA3.

In this example, the material of the anode may be indium tin oxide (ITO) or fluorine-doped tin oxide (FTO). Of course, as required, the material of the anode may further include other film layer(s) or material(s), such as a reflective layer (such as a silver layer), or the anode may be made of other conductive material(s).

In this example, the material of the first hole injection layer may be an organic material or a doped organic material. For example, the material of the first hole injection layer may be PEDOT:PSS, HAT-CN, etc. The solution of the first hole injection layer material may be dripped into a pixel opening by inkjet printing to form the first hole injection layer. Of course, it is understandable that the first hole injection layer may also be prepared by an evaporation process, for example, an open mask+evaporation process is used to prepare the hole injection layer HIL of each quantum dot light-emitting unit QDD.

In this example, the material of the hole transport layer HTL may be an organic material, such as TFB, CBP, etc. The solution of the first hole transport layer material may be dripped into a pixel opening by inkjet printing to form the first hole transport layer. Of course, it is understandable that the first hole transport layer may also be prepared by an evaporation process, for example, an open mask+evaporation process may be used to prepare the hole transport layer HTL of each quantum dot light-emitting unit QDD.

In this example, a solution having a first quantum dot material QDA may be formed as a first quantum dot material layer at a side of the first hole transport layer away from the base substrate BP by a screen printing process, an inkjet printing process, a coating process or other feasible process(processes). In this example, the surface of the first quantum dot material QDA may be modified with organic ligands to improve the solubility of the first quantum dot material QDA and reduce surface defects. Not only that, the organic ligands on the surface of the first quantum dot material QDA may also be cross-linked with each other so that the first quantum dot materials QDA are interconnected, thereby preventing their dissolution and loss in subsequent processes. In other words, in the implementation of the present disclosure, the quantum dots of the first quantum dot material QDA are cross-linked through a second organic matter.

In this example, the first electron transport layer may include metal oxide nanoparticles having an electron transport capability, such as first zinc oxide nanoparticles doped with a low work function metal. For example, the first zinc oxide nanoparticles are doped with 10% to 20% magnesium. In particular, when the first quantum dot light-emitting unit PA is a blue quantum dot light-emitting unit, the first electron transport layer can significantly improve the device performance of the first quantum dot light-emitting unit PA. Furthermore, the first zinc oxide nanoparticles are cross-linked through a first organic matter to prevent the first electron transport layer from being dissolved or corroded during the preparation of subsequent film layers. For example, the surface of the first zinc oxide nanoparticles has cross-linkable ligands (for example, ligands having carbon-carbon double bonds), and the cross-linkable ligands are cross-linked with each other, thereby causing the first zinc oxide nanoparticles to cross-link with each other. For another example, the surface of the first zinc oxide nanoparticles has hydroxyl groups; a cross-linking agent that can be cross-linked with the hydroxyl groups is present in the solution of the first zinc oxide nanoparticles. When preparing the first electron transport layer, the cross-linking agent may be cross-linked with the hydroxyl groups of the first zinc oxide nanoparticles, thereby allowing the first zinc oxide nanoparticles to be cross-linked through an organic matter.

It can be understood that, since the first electron transport layer has metal oxide nanoparticles (such as first zinc oxide nanoparticles), the surface of the first electron transport layer away from the base substrate BP may be relatively rough.

In this example, the N-type charge generation layer NCGL includes metal oxide nanoparticles having an electron transport capability. For example, the N-type charge generation layer NCGL includes second zinc oxide nanoparticles doped with a low work function metal (such as magnesium), or the second zinc oxide nanoparticles are not doped with a metal. The amount of the metal doped in the second zinc oxide nanoparticles is smaller than the amount of the metal doped in the first zinc oxide nanoparticles. This can improve the electron injection effect of the two adjacent first quantum dot tandem layers SubA. In this example, the N-type charge generation layer NCGL has nanoparticles, and thus the roughness of the surface of the N-type charge generation layer NCGL is still relatively large.

In a further scheme, the second zinc oxide nanoparticles are cross-linked through a third organic matter, so that the N-type charge generation layer NCGL forms a whole film layer. This can avoid damaging the N-type charge generation layer NCGL when the P-type charge generation layer PCGL is formed. For example, the surface of the second zinc oxide nanoparticles has cross-linkable ligands (for example, ligands with carbon-carbon double bonds), and the cross-linkable ligands are cross-linked with each other, thereby making the second zinc oxide nanoparticles cross-linked with each other. For another example, the surface of the second zinc oxide nanoparticles has hydroxyl groups; there is a cross-linking agent that can be cross-linked with the hydroxyl groups in the solution of the second zinc oxide nanoparticles. When preparing the first electron transport layer, the cross-linking agent may be cross-linked with the hydroxyl groups of the second zinc oxide nanoparticles, thereby making the second zinc oxide nanoparticles cross-linked through an organic matter. It can be understood that any two of the first organic matter, the second organic matter and the third organic matter may be the same or different.

In the example, the material of the P-type charge generation layer PCGL may be substantially the same as the material of the first hole injection layer; of course, the material of the P-type charge generation layer PCGL may be different from the material of the first hole injection layer, as long as the P-type charge generation layer PCGL has a hole generation capability or a hole injection capability. In this example, since the material of the P-type charge generation layer PCGL can be dissolved in a solvent, the surface of the P-type charge generation layer PCGL (the surface away from the base substrate BP) can be relatively flat, and can produce a certain filling effect on the gap between rough surfaces of N-type charge generation layers NCGL. Therefore, the roughness of the surface of the P-type charge generation layer PCGL away from the base substrate BP is smaller than the roughness of the surface of the N-type charge generation layer NCGL away from the base substrate BP. Furthermore, multiple layers of stacked P-type charge generation layers PCGL may be provided so that the P-type charge generation layers PCGL fully fill the gap between the particles of the N-type charge generation layer NCGL to reduce the risk of current leakage. In this example, an illustrative introduction of the P-type charge generation layer and the N-type charge generation layer is made by taking the normal quantum dot light-emitting unit as an example. It can be understood that in an inverted quantum dot light-emitting unit, the anode is located at a side of the cathode away from the base substrate, so that the P-type charge generation layer is located at a side of the N-type charge generation layer close to the base substrate. In this case, the roughness of the surface of the N-type charge generation layer NCGL close to the base substrate BP is greater than the roughness of the surface of the P-type charge generation layer PCGL close to the base substrate BP.

In an implementation, the second quantum dot light-emitting unit PB includes a quantum dot light-emitting unit QDD of one color, or includes quantum dot light-emitting units QDD of multiple different colors. In the pixel layer, the quantum dot light-emitting units QDD are arranged in an array, in which quantum dot light-emitting units QDD arranged in the same column are quantum dot light-emitting units QDD of the same color. In this way, it is beneficial to prepare each quantum dot light-emitting unit QDD by a solution-based method, especially to facilitate the quantum dot light-emitting units QDD in the same column to share the same film layer (the shared film layer is a common layer), such as sharing one or more of the hole injection layer HIL, the hole transport layer HTL, the quantum dot material layer QDL, the electron transport layer ETL, the N-type charge generation layer NCGL, the P-type charge generation layer PCGL, etc., or sharing other film layer(s).

For example, in the display panel illustrated in FIG. 10, the first quantum dot light-emitting unit PA is a blue quantum dot light-emitting unit B, and the second quantum dot light-emitting unit PB includes quantum dot light-emitting units QDD of two different colors, namely, a red quantum dot light-emitting unit R and a green quantum dot light-emitting unit G. The display panel includes a plurality of red quantum dot light-emitting unit columns, a plurality of green quantum dot light-emitting unit columns, and a plurality of blue quantum dot light-emitting unit columns. A red quantum dot light-emitting unit column includes a plurality of red quantum dot light-emitting units R arranged in sequence along a column direction DV. A green quantum dot light-emitting unit column includes a plurality of green quantum dot light-emitting units G arranged in sequence along the column direction DV. And, a blue quantum dot light-emitting unit column includes a plurality of blue quantum dot light-emitting units B arranged in sequence along the column direction DV.

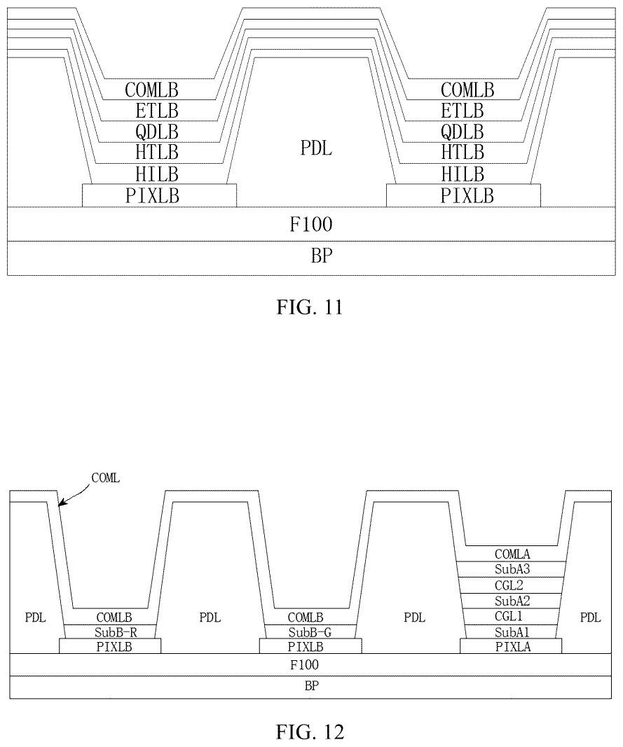

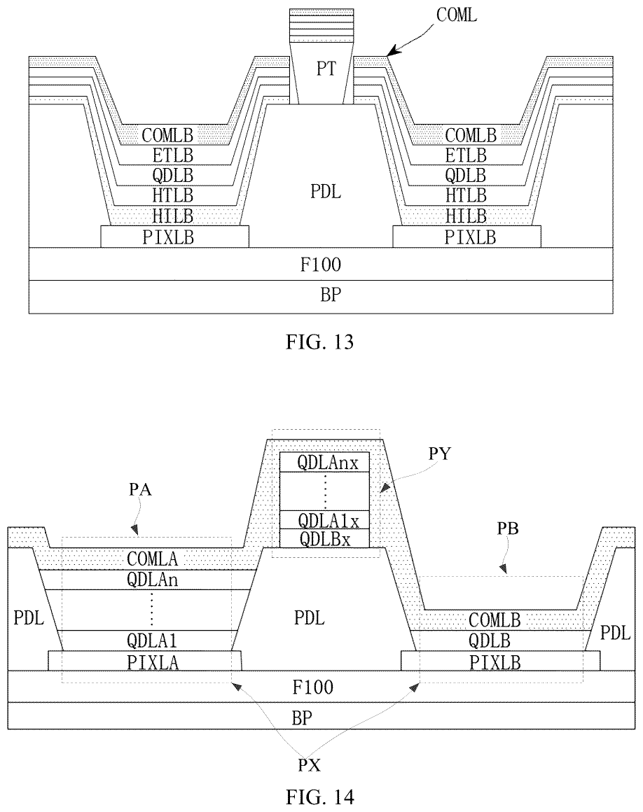

FIG. 11 is a schematic diagram of the structure of the display panel cut at D1-D2 of FIG. 10. FIG. 12 is a schematic diagram of the structure of the display panel cut at D3-D4 of FIG. 10. Referring to FIG. 10 to FIG. 12, in the display panel of this example, the first quantum dot light-emitting unit PA includes three first quantum dot tandem layers SubA, and the second quantum dot light-emitting unit PB includes one second quantum dot tandem layer SubB (for example, a quantum dot tandem layer Sub-R capable of emitting red light and a quantum dot tandem layer Sub-G capable of emitting green light). Referring to FIG. 11, the sub-film layers of the second quantum dot tandem layers SubB of two adjacent second quantum dot light-emitting units PB in the same column may be shared, that is, the sub-film layers of the second quantum dot tandem layers SubB cover the pixel definition layer PDL between the two adjacent second quantum dot light-emitting units PB. In a further scheme, referring to FIG. 13, a partition structure B is provided between two adjacent second quantum dot light-emitting units PB in the same column; at least a part of the film layers of the second quantum dot tandem layers SubB extend to the partition structure PT, and are at least partially broken at the partition structure PT. As an example, a “T”-shaped protrusion may be provided as the partition structure B on the pixel definition layer PDL between two adjacent second quantum dot light-emitting units PB in the same column, or a groove with an opening size smaller than a bottom size may be provided as the partition structure B. In this way, the two adjacent second quantum dot light-emitting units PB along the column direction are isolated from each other, and crosstalk between adjacent second quantum dot light-emitting units PB caused by current leakage on the common layer can be avoided.

Referring to FIG. 12, in the display panel of this example, two quantum dot light-emitting units QDD adjacent to each other in the same row may not have a common layer other than the common electrode layer COML, so that crosstalk between the two quantum dot light-emitting units QDD adjacent to each other in the same row can be avoided. Furthermore, in order to ensure the isolation between the two quantum dot light-emitting units QDD adjacent to each other in the same row, a partition structure may also be provided between the two quantum dot light-emitting units QDD adjacent to each other in the same row. For example, a “T”-shaped protrusion may be provided on the pixel definition layer PDL between the two quantum dot light-emitting units QDD adjacent to each other in the same row, or a groove having an opening size smaller than a bottom size may be provided.

In some other implementations of the present disclosure, the quantum dot light-emitting units QDD of the display panel may be mainly prepared by a deposition process, for example, mainly by an evaporation process, a sputtering process and the like. Furthermore, the main material of the quantum dot light-emitting units QDD may be an inorganic material. When the solution-based method is used for preparation, it is needed to consider the dissolution problem between adjacent film layers, and thus the requirements for the material are relatively high, and it is difficult to achieve high-resolution display products due to limitations of printing equipment, etc. In the implementations of the present disclosure, by mainly using deposition processes such as evaporation or sputtering, etc., the limitations caused by the dissolution problem between materials can be avoided, and it is also beneficial to avoid the constraints of the printing equipment itself on the resolution of the display panel.

In the following, taking the preparation procedure of a kind of first quantum dot light-emitting unit PA as an example, the materials, preparation processes, etc. of film layers of the first quantum dot light-emitting unit PA are illustrative described. In this example, referring to FIG. 13, the first quantum dot light-emitting unit PA is a normal structure. Specifically, the first pixel electrode PIXLA is the anode of the first quantum dot light-emitting unit PA, and the first common electrode COMLA is the cathode of the first quantum dot light-emitting unit PA.

In the example of the first quantum dot light-emitting unit PA of the normal structure, the first quantum dot light-emitting unit PA includes an anode A, a first-layer first quantum dot tandem layer SubA1, a first charge generation layer CGL1, a second-layer first quantum dot tandem layer SubA2, a second charge generation layer CGL2, a third-layer first quantum dot tandem layer SubA3 and a cathode K, which are stacked in sequence. The anode is the first pixel electrode PIXLA, and the cathode is the second common electrode COMLB. In this example, the first quantum dot light-emitting unit PA has three first quantum dot tandem layers SubA. It can be understood that the materials and preparation methods of this example can be adaptively adjusted and applied to a first quantum dot light-emitting unit PA having other numbers of layers of first quantum dot tandem layers SubA, for example, it is also applicable to a first quantum dot light-emitting unit PA having two layers of first quantum dot tandem layers SubA.

In this example, any one first quantum dot tandem layer SubA includes a first hole injection layer, a first hole transport layer, a first quantum dot material layer, a first protective layer PRLA, and a first electron transport layer, which are stacked in sequence. For example, the first-layer first quantum dot tandem layer SubA1 includes a first-layer first hole injection layer HILA1, a first-layer first hole transport layer HTLA1, a first-layer first quantum dot material layer QDLA1, a first-layer first protective layer PRLA1, and a first-layer first electron transport layer ETLA1, which are stacked in sequence. The second-layer first quantum dot tandem layer SubA2 includes a second-layer first hole injection layer HILA2, a second-layer first hole transport layer HTLA2, a second-layer first quantum dot material layer QDLA2, a second-layer first protective layer PRLA2, and a second-layer first electron transport layer ETLA2, which are stacked in sequence. The third-layer first quantum dot tandem layer SubA3 includes a third-layer first hole injection layer HILA3, a third-layer first hole transport layer HTLA3, a third-layer first quantum dot material layer QDLA3, a third-layer first protective layer PRLA3, and a third-layer first electron transport layer ETLA3, which are stacked in sequence.

In this example, any one layer of charge generation layer CGL includes an N-type charge generation layer NCGL and a P-type charge generation layer PCGL which are stacked in sequence. The N-type charge generation layer NCGL is arranged adjacent to a first electron transport layer of an adjacent first quantum dot tandem layer SubA. The P-type charge generation layer PCGL is arranged adjacent to a first hole injection layer of the adjacent first quantum dot tandem layer SubA. For example, the first charge generation layer CGL1 includes a first N-type charge generation layer NCGL1 and a first P-type charge generation layer PCGL1 which are stacked. The first N-type charge generation layer NCGL1 is arranged adjacent to the first-layer first electron transport layer ETLA1, and the first P-type charge generation layer PCGL1 is arranged adjacent to the second-layer first hole injection layer HILA2. The second charge generation layer CGL2 includes a second N-type charge generation layer NCGL2 and a second P-type charge generation layer PCGL2 which are stacked. The second N-type charge generation layer NCGL2 is arranged adjacent to the second-layer first electron transport layer ETLA2, and the second P-type charge generation layer PCGL2 is arranged adjacent to the third-layer first hole injection layer HILA3.

In this example, the material of the first hole injection layer may be an inorganic material, such as a metal oxide doped with or not doped with a metal. For example, the material of the first hole injection layer may be molybdenum oxide, nickel oxide, etc., and the molybdenum oxide or nickel oxide may be doped with a high work function metal, such as aluminum. The material of the first hole injection layer is an inorganic material, which may be prepared by a deposition process such as evaporation or sputtering (such as magnetron sputtering). For example, a molybdenum oxide thin film may be formed by an evaporation process as the first hole injection layer, or a nickel oxide thin film may be formed by a sputtering process as the first hole injection layer. In this example, since the first hole injection layer is prepared by a sputtering process or an evaporation process, the surface of the first hole injection layer away from the base substrate BP has a high flatness, for example, the surface roughness (root mean square surface roughness RMS) of the surface of the first hole injection layer away from the base substrate BP is smaller than 10 nanometers. Furthermore, by controlling the process parameter(s) of the evaporation process or the sputtering process, the surface roughness of the surface of the first hole injection layer away from the base substrate BP is smaller than 2 nanometers. This can improve the uniformity of the first hole injection layer, and thus improve the in-plane current uniformity of the first quantum dot tandem layer SubA. In a feasible scheme, the first hole injection layer is a molybdenum oxide thin film. The molybdenum oxide thin film may be prepared by an evaporation process, so that the thickness uniformity of the first hole injection layer is better and has fewer surface defects, thereby ensuring the in-plane current uniformity of the first quantum dot tandem layer SubA and reducing the short circuit risk of the first quantum dot tandem layer SubA.

In this example, the material of the first hole transport layer may be an inorganic material, such as a metal oxide doped with or not doped with a metal. For example, the material of the first hole transport layer may be tungsten oxide, vanadium oxide, etc., and tungsten oxide or vanadium oxide may be doped with a high work function metal, such as aluminum or silver. The material of the first hole transport layer is an inorganic material, which may be prepared by a deposition process such as evaporation or sputtering (such as magnetron sputtering). For example, a vanadium oxide thin film may be formed by an evaporation process as the first hole transport layer, or a tungsten oxide thin film may be formed by a sputtering process as the first hole transport layer. In this example, since the first hole transport layer is prepared by a sputtering process or an evaporation process, the surface of the first hole transport layer away from the base substrate BP has a high flatness, for example, the surface roughness (root mean square surface roughness RSM) of the surface of the first hole transport layer away from the base substrate BP is smaller than 10 nanometers. Furthermore, by controlling the process parameters of the evaporation process or the sputtering process, the surface roughness of the surface of the first hole transport layer away from the base substrate BP is smaller than 2 nanometers. This can improve the uniformity of the first hole transport layer, and thus improve the in-plane current uniformity of the quantum dot tandem layer Sub. In a feasible scheme, the first hole transport layer is a vanadium oxide thin film; the vanadium oxide thin film can be prepared by an evaporation process, so that the thickness uniformity of the first hole transport layer is better and has fewer surface defects, thereby ensuring the in-plane current uniformity of the quantum dot tandem layer Sub and reducing the short circuit risk of the quantum dot tandem layer Sub.

In this example, a first quantum dot material layer may be formed at a side of the first hole transport layer away from the base substrate BP by a printing process, a pressing process, a coating process or other feasible processes. For example, a first quantum dot material QDA solution may be coated on a surface of the first hole transport layer away from the base substrate BP, and the first quantum dot material layer may be formed after the solvent of the first quantum dot material QDA solution evaporates. In this example, the surface of the first quantum dot material QDA may be modified with an organic ligand to improve the solubility of the first quantum dot material QDA and reduce surface defects. Of course, in some other examples, the first quantum dot materials QDA may also be cross-linked with each other.

In an example, the material of the first protective layer PRLA may be an organic material with an electron transport capability, and in particular, may be an electron transport type organic polymer material. The first protective layer PRLA may be formed at a side of the first quantum dot material layer away from the base substrate BP by an evaporation or solution process (e.g., coating process). The first protective layer PRLA may protect the first quantum dot material layer, and prevent the subsequent first electron transport layer preparation process from damaging the first quantum dot material QDA, and in particular, prevent the high energy of the sputtering process from damaging the organic ligands on the surface of the first quantum dot material QDA. In this way, the first electron transport layer preparation process will not cause defects in the first quantum dot material QDA, thereby ensuring the luminous efficiency of the first quantum dot material layer. In a further feasible scheme, the thickness of the first protective layer PRLA does not exceed 10 nanometers, for example, between 5 and 9 nanometers. In this way, the first protective layer PRLA can both protect the first quantum dot material QDA and avoid excessively reducing the efficiency of injecting electrons into the first quantum dot material layer due to excessive thickness.

In another example, the material of the first protective layer PRLA may be a metal oxide doped with or undoped with a metal, such as molybdenum oxide or molybdenum oxide doped with a metal (such as magnesium or aluminum, etc.). In a further feasible scheme, a molybdenum oxide thin film may be formed by an evaporation process as the first protective layer PRLA. The energy of the evaporation process is small, and thus the surface organic ligands of the first quantum dot material QDA will not be damaged. On the one hand, in the subsequent procedure of forming the first electron transport layer, the molybdenum oxide thin film may protect the first quantum dot material QDA and prevent the organic ligands on the surface of the first quantum dot material QDA from being damaged in the sputtering process. On the other hand, the molybdenum oxide thin film can block electrons to a certain extent, thereby regulating the efficiency of electron injection into the first quantum dot material layer, improving the balance of electron and hole injection into the first quantum dot material layer, and thereby facilitating the improvement of the luminous efficiency of the first quantum dot material layer. Optionally, the thickness of the molybdenum oxide thin film does not exceed 10 nanometers, for example, it may be 5 to 9 nanometers, thereby avoiding the excessive reduction of the efficiency of electron injection into the first quantum dot material layer due to the excessive thickness of the molybdenum oxide thin film.

In this example, the material of the first electron transport layer may be zinc oxide doped with a low work function metal or may be a metal oxide with an electron transport capability, such as zinc magnesium oxide. The first electron transport layer may be prepared by a sputtering process. In the procedure of preparing the first electron transport layer, the surface of the first protective layer PRLA may be damaged due to the high energy of sputtering, thereby making the surface of the first protective layer PRLA away from the base substrate BP relatively rough. However, the surface roughness of the first protective layer PRLA can enhance the light emission effect and help improve the external quantum efficiency of the first quantum dot light-emitting unit PA. In this example, since the first electron transport layer is prepared by a sputtering process, the surface of the first electron transport layer away from the base substrate BP has a high flatness, for example, the surface roughness (root mean square surface roughness RSM) of the surface of the first electron transport layer away from the base substrate BP is smaller than 10 nanometers. Further, by controlling the process parameters of the sputtering process, the surface roughness of the surface of the first electron transport layer away from the base substrate BP is smaller than 2 nanometers. This can improve the uniformity of the first electron transport layer, thereby improving the in-plane current uniformity of the first quantum dot tandem layer SubA. In this example, the roughness of the surface of the first electron transport layer ETLA away from the base substrate is smaller than the roughness of the surface of the first protective layer PRLA close to the base substrate.

In this example, the material of the P-type charge generation layer PCGL may be zinc magnesium oxide, or zinc oxide. The N-type charge generation layer NCGL may be prepared at a side of the first electron transport layer away from the base substrate BP by a sputtering process. In a feasible scheme, the magnesium content in the N-type charge generation layer NCGL is lower than the magnesium content in the first electron transport layer. In this way, the energy levels of the N-type charge generation layer NCGL, the first electron transport layer, and the first quantum dot material layer are more matched, which can more effectively improve the luminous efficiency of the first quantum dot tandem layer SubA. In a further scheme, the material of the N-type charge generation layer NCGL is zinc oxide, which does not contain magnesium oxide or is not doped with magnesium.

In this example, the material of the P-type charge generation layer PCGL may be molybdenum oxide or nickel oxide.

In an implementation, each quantum dot light-emitting unit QDD may be prepared mainly by deposition processes such as evaporation or sputtering, etc., and thus each quantum dot light-emitting unit QDD may be arranged as needed, and it is not needed to make the quantum dot light-emitting units QDD in the same column be quantum dot light-emitting units QDD of the same color.

In an implementation, three different strategies can be used to prepare the quantum dot light-emitting units QDD in the pixel layer, namely, all charge layers are shared, a part of the charge layers are shared, and the charge layers are made separately.

In an example, a strategy of sharing all charge layers may be adopted to prepare the first quantum dot light-emitting unit PA and the second quantum dot light-emitting unit PB. Specifically, in the procedure of preparing the pixel layer, respective charge layers may cover the display region AA without a patterning operation, and only the quantum dot material layer QDL needs to be patterned. This makes the patterning process (for example, including coating photoresist, exposure, development, etching, removing photoresist, etc.) in the pixel layer preparation procedure relatively small, which can greatly reduce the preparation cost of the display panel. In addition, since the number of layers of the first quantum dot material layers is more than the number of layers of the second quantum dot material layer(s) QDLB, a second quantum dot material layer QDLB may be protected by a charge layer during the patterning procedure of at least a part of the first quantum dot material layers, thereby reducing the impact of the patterning process (especially the etching process) on the second quantum dot material layer QDLB.

For example, the first quantum dot light-emitting unit PA includes two first quantum dot tandem layers SubA, and the second quantum dot light-emitting unit PB includes one second quantum dot tandem layer SubB. During preparation, the entire first-layer hole injection layer HIL1 and first-layer hole transport layer HTL1 may be prepared in sequence. A part of the first-layer hole injection layer HIL1 in contact with the first pixel electrode PIXLA serves as the first-layer first hole injection layer HILA1, and a part of the first-layer hole injection layer HIL1 in contact with the second pixel electrode PIXLB serves as the second hole injection layer HILB. A part of the first-layer hole transport layer HTL1 overlapping with the first-layer first hole injection layer HILA1 serves as the first-layer first hole transport layer HTLA1, and a part of the first-layer hole transport layer HTL1 overlapping with the second hole injection layer HILB serves as the second hole transport layer HTLB. Then, the first-layer first quantum dot material layer QDLA1 of the first quantum dot light-emitting unit PA and the second quantum dot material layer QDLB of the second quantum dot light-emitting unit PB are respectively prepared. In the preparation procedure, the first-layer first quantum dot material layer QDLA1 and the second quantum dot material layer QDLB may be patterned by a patterning process. For example, if the first quantum dot light-emitting unit PA is a blue quantum dot light-emitting unit and the second quantum dot light-emitting unit PB includes a red quantum dot light-emitting unit and a green quantum dot light-emitting unit, it is needed to prepare a blue quantum dot material layer and pattern it, prepare a red quantum dot material layer and pattern it, and prepare a green quantum dot material layer and pattern it. Then, the entire first-layer electron transport layer ETL1 is prepared. A part of the first-layer electron transport layer ETL1 overlapping with the first-layer first hole injection layer HILA1 serves as the first-layer first electron transport layer ETLA1, and a part of the first-layer electron transport layer ETL1 overlapping with the second hole injection layer HILB serves as the second electron transport layer ETLB. Then, the entire N-type charge generation layer NCGL, P-type charge generation layer PCGL, the second-layer hole injection layer HIL2, the second-layer hole transport layer HTL2 are prepared in sequence, and parts of these film layers overlapping with the first-layer first hole injection layer HILA1 are respectively used as the N-type charge generation layer NCGL, the P-type charge generation layer PCGL, the second-layer first hole injection layer HILA2, the second-layer first hole transport layer HTLA2, and then the second-layer first quantum dot material layer QDLA2 is prepared and patterned. When the second-layer first quantum dot material layer QDLA2 is patterned, the second quantum dot material layer QDLB has been covered and protected by film layers such as the first-layer electron transport layer ETL1, the N-type charge generation layer NCGL, the P-type charge generation layer PCGL, the second-layer hole injection layer HIL2, the second-layer hole transport layer HTL2, etc., and thus it will not be damaged during the patterning process of the second-layer first quantum dot material layer QDLA2. Then, the entire second-layer electron transport layer ETL2 and the common electrode layer COML are prepared.

In an example, a strategy of partially sharing the charge layer(s) may be used to prepare the first quantum dot light-emitting unit PA and the second quantum dot light-emitting unit PB. Specifically, in the procedure of preparing the pixel layer, a part of the charge layers may cover the display region AA without a patterning operation, and a part of the charge layers needs patterning.

For example, the first quantum dot light-emitting unit PA includes two first quantum dot tandem layers SubA, and the second quantum dot light-emitting unit PB includes one second quantum dot tandem layer SubB. During preparation, the entire first-layer hole injection layer HIL1 and the first-layer hole transport layer HTL1 may be prepared in sequence. A part of the first-layer hole injection layer HIL1 in contact with the first pixel electrode PIXLA serves as the first-layer first hole injection layer HILA1, and a part of the first-layer hole injection layer HIL1 in contact with the second pixel electrode PIXLB serves as the second hole injection layer HILB. A part of the first-layer hole transport layer HTL1 overlapping with the first-layer first hole injection layer HILA1 serves as the first-layer first hole transport layer HTLA1, and a part of the first-layer hole transport layer HTL1 overlapping with the second hole injection layer HILB serves as the second hole transport layer HTLB. Then, the first-layer first quantum dot material layer QDLA1 of the first quantum dot light-emitting unit PA and the second quantum dot material layer QDLB of the second quantum dot light-emitting unit PB are respectively prepared. In the preparation procedure, the first-layer first quantum dot material layer QDLA1 and the second quantum dot material layer QDLB may be patterned by a patterning process. For example, if the first quantum dot light-emitting unit PA is a blue quantum dot light-emitting unit and the second quantum dot light-emitting unit PB includes a red quantum dot light-emitting unit and a green quantum dot light-emitting unit, it is needed to prepare a blue quantum dot material layer and pattern it, prepare a red quantum dot material layer and pattern it, and prepare a green quantum dot material layer and pattern it. Then, the entire first-layer electron transport layer ETL1 and the N-type charge generation layer NCGL are prepared. Afterwards, the P-type charge generation layer PCGL, the second-layer hole injection layer HIL2, the second-layer hole transport layer HTL2, the second-layer first quantum dot material layer QDLA2, and the second-layer electron transport layer ETL2 are prepared in the region where the first quantum dot light-emitting unit PA is located. That is, the P-type charge generation layer PCGL is prepared and patterned, so that the P-type charge generation layer PCGL covers the region where the first quantum dot light-emitting unit PA is located and exposes the region where the second quantum dot light-emitting unit PB is located. The second-layer hole injection layer HIL2 is prepared and patterned, so that the second-layer hole injection layer HIL2 covers the region where the first quantum dot light-emitting unit PA is located and exposes the region where the second quantum dot light-emitting unit PB is located. The second-layer hole transport layer HTL2 is prepared and patterned, so that the second-layer hole transport layer HTL2 covers the region where the first quantum dot light-emitting unit PA is located and exposes the region where the second quantum dot light-emitting unit PB is located. The second-layer first quantum dot material layer QDLA2 is prepared and patterned, so that the second-layer first quantum dot material layer QDLA2 covers the region where the first quantum dot light-emitting unit PA is located and exposes the region where the second quantum dot light-emitting unit PB is located. The second-layer electron transport layer ETL2 is prepared and patterned, so that the second-layer electron transport layer ETL2 covers the region where the first quantum dot light-emitting unit PA is located and exposes the region where the second quantum dot light-emitting unit PB is located. Then, a whole common electrode layer COML is prepared. In this example, there are no film layers such as the P-type charge generation layer PCGL, second-layer hole injection layer HIL2, second-layer hole transport layer HTL2, second-layer electron transport layer ETL2 above the second quantum dot material layer QDLB of the second quantum dot light-emitting unit PB (on the side away from the base substrate BP). Therefore, the light output loss of the second quantum dot material layer QDLB is small, which can improve the light output efficiency of the second quantum dot light-emitting unit PB, thereby helping to reduce power consumption.

In an example, a strategy of separately making charge layers maybe adopted to prepare respective quantum dot light-emitting units QDD. Specifically, in the procedure of preparing the pixel layer, the charge layers of quantum dot light-emitting units QDD of different colors are prepared separately, which can ensure the best match between the charge layers and the quantum dot material layers QDL, thereby facilitating the improvement of the efficiency of each quantum dot light-emitting unit QDD.

For example, the first quantum dot light-emitting unit PA includes two first quantum dot tandem layers SubA, and the second quantum dot light-emitting unit PB includes a red quantum dot light-emitting unit and a green quantum dot light-emitting unit. When preparing the first quantum dot light-emitting unit PA, film layers such as the first-layer first hole injection layer HILA1, the first-layer first hole transport layer HTLA1, the first-layer first quantum dot material layer QDLA1, the first-layer first electron transport layer ETLA1, the N-type charge generation layer NCGL, the P-type charge generation layer PCGL, the second-layer first hole injection layer HILA2, the second-layer first hole transport layer HTLA2, the second-layer first quantum dot material layer QDLA2, the second-layer first electron transport layer ETLA2, etc. are prepared in sequence, and respective film layers are subjected to a patterning operation and only cover the region where the first quantum dot light-emitting unit PA is located. When preparing the red quantum dot light-emitting unit, film layers required for the quantum dot light-emitting unit such as the second hole injection layer, the second hole transport layer, the red quantum dot material layer, the second electron transport layer may be prepared in sequence, and respective film layers are subjected to a patterning operation and only cover the region where the red quantum dot light-emitting unit is located. When preparing the green quantum dot light-emitting unit, film layers required for the green quantum dot light-emitting unit such as the second hole injection layer HIL, the second hole transport layer HTL, the green quantum dot material layer, the second electron transport layer ETL may be prepared in sequence, and respective film layers are subjected to a patterning operation and only cover the region where the green quantum dot light-emitting unit is located.

In this implementation, when preparing respective quantum dot light-emitting units QDD, the surface of the pixel definition layer PDL may be damaged when a process such as sputtering is used, thereby making the surface of the pixel definition layer PDL rough. Therefore, the surface of the pixel definition layer PDL is uneven, which in turn makes the charge layer located on the surface of the pixel definition layer PDL uneven or partially broken. Therefore, it is difficult for the quantum dot light-emitting unit QDD to leak electricity through the charge layer(s) on the surface of the pixel definition layer PDL, which can reduce or eliminate the crosstalk between adjacent quantum dot light-emitting units QDD. In other words, in this implementation, a partition structure may not need to be provided on the pixel definition layer PDL between adjacent quantum dot light-emitting units QDD, so that the crosstalk between adjacent quantum dot light-emitting units QDD can be reduced or eliminated, and the structure of the display panel can be simplified.

In this implementation, the surface of the pixel opening of the pixel definition layer PDL is also damaged by sputtering, which makes the surface of the pixel opening rough. Therefore, the light emitted by the quantum dot light-emitting unit QDD located in the pixel opening can be reflected by a side wall of the pixel definition layer PDL, thereby improving the light extraction efficiency. For example, the pixel opening of the pixel definition layer PDL is a trapezoidal structure with a large opening and a small bottom surface, which makes the cross-section of the pixel definition layer PDL between adjacent quantum dot light-emitting units QDD trapezoidal, and its side surface is rough due to sputtering damage, thereby enhancing the reflection of the emitted light of the quantum dot light-emitting units QDD.

In some implementations of the present disclosure, when preparing the quantum dot light-emitting units QDD, the quantum dot material layer QDL may be made to cover the display region AA and then a patterning operation is performed. However, referring to FIG. 14, during the patterning process, there may be a phenomenon in which the quantum dot material layer QDL may not be completely removed and may have a residual, or the quantum dot material layer QDL may also cover a region between the quantum dot light-emitting units QDD without being removed. Therefore, in the implementations of the present disclosure, a part of the pixel layer provided with quantum dot light-emitting unit(s) QDD may be referred to as a first part PX, and a part of the pixel layer not provided with a quantum dot light-emitting unit QDD but with the residual or having retained quantum dot material layer QDL may be referred to as a second part PY. The quantum dot material layer QDL is provided in both the first part PX and the second part PY. For example, a first quantum dot light-emitting unit of the first part includes n stacked first quantum dot material layers (QDLA1 to QDLAn), and a second quantum dot light-emitting unit of the first part includes one second quantum dot material layer QDLB. The second part includes at least one second quantum dot material layer QDLBx and n stacked first quantum dot material layers (QDLA1x to QDLAnx) which are stacked. The orthographic projection of the first part PX on the base substrate BP is located within the orthographic projection of the pixel electrode on the base substrate BP; the first part PX is located at a side of the pixel electrode away from the base substrate BP. The orthographic projection of the second part PY on the base substrate BP is located outside the orthographic projection of the pixel electrode on the base substrate BP. Further, the orthographic projection of the second part PY on the base substrate BP is located within the orthographic projection of the top end surface of the pixel definition layer PDL (the end surface of the pixel definition layer PDL away from the base substrate BP) on the base substrate BP. In the first part PX, only the quantum dot material layer QDL used for light emission is retained, while in the second part PY, each quantum dot material layer QDL in the preparation procedure of display panel may be residual or each quantum dot material layer QDL in the preparation procedure of display panel may be retained here. Therefore, the number of quantum dot material layers QDL possessed by at least part of the first part PX is smaller than the number of quantum dot material layers QDL possessed by at least part of the second part PY.

In some examples, the quantum dot material layer(s) QDL in the second part PY is(are) a residue from a process of preparing the quantum dot material layer(s) QDL, and thus the thickness of the quantum dot material layer(s) QDL in the second part PY is smaller than the thickness of the quantum dot material layer(s) QDL in the first part PX.

The present disclosure also provides a display device, which includes any one of the display panels described in the above display panel implementations. The display device may be a smartphone screen, a smart watch screen, or other types of display devices. Since the display device includes any one of the display panels described in the above display panel implementations, it has the same beneficial effects, and repeated description will be omitted in the present disclosure.

Those skilled in the art will readily appreciate other implementations of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be illustrative only, and the true scope and spirit of the present disclosure are indicated by the appended claims.

1. A display panel, comprising a base substrate and a pixel layer stacked at a side of the base substrate, wherein the pixel layer comprises at least two regions, each of the at least two regions is provided with at least one quantum dot material layer, and the number of the at least one quantum dot material layer provided in one region of the at least two regions is greater than the number of the at least one quantum dot material layer provided in the other region of the at least two regions.

2. The display panel according to claim 1, wherein the pixel layer comprises a first quantum dot light-emitting unit and a second quantum dot light-emitting unit arranged side by side;
wherein the first quantum dot light-emitting unit comprises a first pixel electrode, n first quantum dot tandem layers and a first common electrode which are stacked in sequence at the side of the base substrate,
wherein the second quantum dot light-emitting unit comprises a second pixel electrode, m second quantum dot tandem layers and a second common electrode which are stacked in sequence at the side of the base substrate;
wherein each of the first quantum dot tandem layers and the second quantum dot tandem layers is provided with a quantum dot material layer;
wherein a light-emitting wavelength of the first quantum dot light-emitting unit is shorter than a light-emitting wavelength of the second quantum dot light-emitting unit;
wherein n and m are both positive integers greater than or equal to 1, and n>m.

3. The display panel according to claim 2, wherein n is greater than m by 1 or 2.

4. The display panel according to claim 2, wherein a step difference between a surface of the first quantum dot light-emitting unit away from the base substrate and a surface of the second quantum dot light-emitting unit away from the base substrate does not exceed 400 nm.

5. The display panel according to claim 2, wherein the display panel further comprises a thin film encapsulation layer at a side of the pixel layer away from the base substrate, and a thickness of a part of the thin film encapsulation layer that overlaps with the first quantum dot light-emitting unit is smaller than a thickness of a part of the thin film encapsulation layer that overlaps with the second quantum dot light-emitting unit.

6. The display panel according to claim 2, wherein the second quantum dot light-emitting unit comprises a quantum dot light-emitting unit of a color, or comprises quantum dot light-emitting units of a plurality of different colors;
wherein an area ratio of the first quantum dot light-emitting unit is greater than an area ratio of a quantum dot light-emitting unit of any one of the colors in the second quantum dot light-emitting unit.

7. The display panel according to claim 2, wherein the display panel further comprises a driving layer between the base substrate and the pixel layer, the driving layer has a first pixel driving circuit configured to drive the first quantum dot light-emitting unit and a second pixel driving circuit configured to drive the second quantum dot light-emitting unit, and the driving layer comprises a first power supply voltage line connected to the first pixel driving circuit and a second power supply voltage line connected to the second pixel driving circuit;
wherein the first pixel electrode is electrically connected to the first power supply voltage line through the first pixel driving circuit, and the first quantum dot light-emitting unit is configured to emit light under driving of a driving current between the first power supply voltage line and the first common electrode;
wherein the second pixel electrode is electrically connected to the second power supply voltage line through the second pixel driving circuit, and the second quantum dot light-emitting unit is configured to emit light under driving of a driving current between the second power supply voltage line and the second common electrode;
wherein the first power supply voltage line and the second power supply voltage line are capable of being applied with different power supply voltages respectively.

8. The display panel according to claim 7, wherein a width of the first power supply voltage line is greater than a width of the second power supply voltage line.

9. The display panel according to claim 2, wherein the second quantum dot light-emitting unit comprises a quantum dot light-emitting unit of a color, or comprises quantum dot light-emitting units of a plurality of different colors;
wherein in the pixel layer, quantum dot light-emitting units are arranged in an array, wherein quantum dot light-emitting units arranged in a same column are quantum dot light-emitting units of a same color.

10. The display panel according to claim 9, wherein a partition structure is provided between two adjacent first quantum dot light-emitting units in a same column, and at least a part of film layers of the two adjacent quantum dot light-emitting units extend to the partition structure and are at least partially broken at the partition structure; and/or
wherein a partition structure is provided between two adjacent second quantum dot light-emitting units in a same column, and at least a part of film layers of the two adjacent second quantum dot light-emitting units extend to the partition structure and are at least partially broken at the partition structure.

11. The display panel according to claim 2, wherein one of the first quantum dot tandem layers comprises a first quantum dot material layer and a first electron transport layer which are stacked, the first electron transport layer comprises first zinc oxide nanoparticles doped with a metal, the first zinc oxide nanoparticles are cross-linked through a first organic matter, and the first quantum dot material layer comprises quantum dots cross-linked through a second organic matter.

12. The display panel according to claim 11, wherein the first quantum dot light-emitting unit further comprises a charge generation layer between adjacent first quantum dot tandem layers, and the charge generation layer comprises an N-type charge generation layer arranged adjacent to the first electron transport layer;
wherein the N-type charge generation layer comprises second zinc oxide nanoparticles, an amount of a metal doped in the second zinc oxide nanoparticles is smaller than an amount of the metal doped in the first zinc oxide nanoparticles or the second zinc oxide nanoparticles are not doped with a metal, and the second zinc oxide nanoparticles are cross-linked through a third organic matter.

13. The display panel according to claim 11, wherein the first electron transport layer is at a side of the first quantum dot material layer away from the base substrate;
wherein the first quantum dot light-emitting unit further comprises a charge generation layer between adjacent first quantum dot tandem layers, and the charge generation layer comprises a P-type charge generation layer and an N-type charge generation layer stacked in sequence at a side of the first electron transport layer away from the base substrate;
wherein roughness of a surface of the N-type charge generation layer away from the base substrate is greater than roughness of a surface of the P-type charge generation layer away from the base substrate.

14. The display panel according to claim 13, wherein the charge generation layer comprises at least one N-type charge generation layer and a plurality of P-type charge generation layers, and the number of the P-type charge generation layers is greater than the number of the at least one N-type charge generation layer;
wherein roughness of a surface of a P-type charge generation layer, which is the farthest from the N-type charge generation layer, away from the base substrate is smaller than roughness of a surface of the N-type charge generation layer away from the base substrate.

15. The display panel according to claim 2, wherein one of the first quantum dot tandem layers comprises a first quantum dot material layer, a first protective layer and a first electron transport layer which are stacked in sequence, the first protective layer is arranged on a surface of the first quantum dot material layer away from the base substrate, and roughness of a surface of the first electron transport layer away from the base substrate is smaller than roughness of a surface of the first protective layer close to the base substrate.

16. The display panel according to claim 15, wherein a material of the first protective layer is an electron-transporting polymer or molybdenum oxide; or
wherein a thickness of the first protective layer does not exceed 10 nanometers; or
wherein the pixel layer further comprises a pixel definition layer, the pixel definition layer having a first pixel opening exposing at least partial region of the first pixel electrode and a second pixel opening exposing at least partial region of the second pixel electrode, the first quantum dot tandem layer covers the first pixel electrode exposed by the first pixel opening, and the second quantum dot tandem layer covers the second pixel electrode exposed by the second pixel opening;
wherein in the display region of the display panel, roughness of a side surface and a top surface of the pixel definition layer is greater than roughness of surfaces of the first pixel electrode and the second pixel electrode.

17-18. (canceled)

19. The display panel according to claim 1, wherein the pixel layer comprises a first part and a second part arranged side by side, and the first part and the second part are both provided with a quantum dot material layer;
wherein the pixel layer is further provided with a pixel electrode;
wherein an orthographic projection of the first part on the base substrate is located within an orthographic projection of the pixel electrode on the base substrate, and the first part is at a side of the pixel electrode away from the base substrate;
wherein an orthographic projection of the second part on the base substrate is located outside the orthographic projection of the pixel electrode on the base substrate;
wherein the number of quantum dot material layers comprised in at least a part of the first part is smaller than the number of quantum dot material layers comprised in at least a part of the second part.

20. The display panel according to claim 19, wherein a thickness of at least a part of the quantum dot material layers in the second part is smaller than a thickness of at least a part of the quantum dot material layers in the first part.

21. The display panel according to claim 20, wherein the first part comprises a first quantum dot light-emitting unit and a second quantum dot light-emitting unit arranged side by side;
wherein the first quantum dot light-emitting unit comprises a first pixel electrode, n first quantum dot tandem layers and a first common electrode stacked in sequence at a side of the base substrate, the second quantum dot light-emitting unit comprises a second pixel electrode, m second quantum dot tandem layers and a second common electrode stacked in sequence at a side of the base substrate, and each of the first quantum dot tandem layers and the second quantum dot tandem layers is provided with a quantum dot material layer;
wherein an light-emitting wavelength of the first quantum dot light-emitting unit is shorter than an light-emitting wavelength of the second quantum dot light-emitting unit;
wherein n and m are both positive integers greater than or equal to 1, and n>m.

22. A display device comprising a display panel;
wherein the display panel comprises a base substrate and a pixel layer stacked at a side of the base substrate, the pixel layer comprises at least two regions, each of the at least two regions is provided with at least one quantum dot material layer, and the number of the at least one quantum dot material layer provided in one region of the at least two regions is greater than the number of the at least one quantum dot material layer provided in the other region of the at least two regions.
